(19) United States
(12) Patent Application Publication
(10) Pub. No.: US 2026/0182160 A1
(43) Pub. Date: Jun. 25, 2026

(54) DISPLAY DEVICE, METHOD OF MANUFACTURING DISPLAY DEVICE AND ELECTRONIC DEVICE

(71) Applicant: Samsung Display Co., Ltd., Yongin-si (KR)

(72) Inventors: YOUNGROK KIM, Yongin-si (KR); Dongjun Kim, Yongin-si (KR); KYU-SOON PARK, Yongin-si (KR); WOOJIN CHO, Yongin-si (KR)

(21) Appl. No.: 19/307,639

(22) Filed: Aug. 22, 2025

(30) Foreign Application Priority Data
Dec. 19, 2024 (KR) 10-2024-0190992

(51) Int. Cl. H10K 59/123; H10K 59/12; H10K 59/122; H10K 59/124; H10K 59/80; H10K 71/60

(52) U.S. Cl. CPC H10K 59/123; H10K 59/1201; H10K 59/122; H10K 59/124; H10K 59/8051; H10K 71/60

(57) ABSTRACT

A display device includes a transistor above a substrate, a first insulating layer above the transistor, a second insulating layer above the first insulating layer and defining a first sub-opening, a light-emitting element above the second insulating layer, electrically connected to the transistor, and including a first electrode, an intermediate layer above the first electrode, and a second electrode above the intermediate layer, a pixel-defining layer above the second insulating layer, covering at least a portion of the first electrode, and defining a third sub-opening, wherein the third sub-opening overlaps the first sub-opening in a plan view and is connected to the first sub-opening to define a first opening, and a separator between the second insulating layer and the pixel-defining layer, and protruding into the first opening.

### CROSS-REFERENCE TO RELATED APPLICATION

The present application claims priority to, and the benefit of, Korean Patent Application No. 10-2024-0190992, filed on Dec. 19, 2024, in the Korean Intellectual Property Office, the entire disclosure of which is incorporated herein by reference.

### BACKGROUND

### 1. Field

Embodiments relate to a display device that provides visual information, a method of manufacturing the display device, and an electronic device including the display device.

### 2. Description of the Related Art

With development of information technology, importance of a display device, which is a connecting medium between a user and information, is being highlighted. The display device includes a light-emitting element and a pixel-driving circuit for driving the light-emitting element. The light-emitting element is driven by the pixel-driving circuit to emit light. To improve reliability of the display device, research on a connection between the light-emitting element and the pixel-driving circuit is ongoing.

### SUMMARY

Embodiments provide a display device with improved efficiency in a manufacturing process.

Embodiments provide a method of manufacturing the display device.

Embodiments provide an electronic device including the display device.

A display device according to one or more embodiments of the present disclosure includes a transistor above a substrate, a first insulating layer above the transistor, a second insulating layer above the first insulating layer and defining a first sub-opening, a light-emitting element above the second insulating layer, electrically connected to the transistor, and including a first electrode, an intermediate layer above the first electrode, and a second electrode above the intermediate layer, a pixel-defining layer above the second insulating layer, covering at least a portion of the first electrode, and defining a third sub-opening, wherein the third sub-opening overlaps the first sub-opening in a plan view and is connected to the first sub-opening to define a first opening, and a separator between the second insulating layer and the pixel-defining layer, and protruding into the first opening.

The separator and the first electrode may be at a same layer.

The separator and the first electrode may include a same material.

The first insulating layer may define a groove in a recessed portion of an upper surface of the first insulating layer, wherein the second insulating layer further defines a second sub-opening overlapping the groove in the plan view, wherein the pixel-defining layer further defines a fourth sub-opening overlapping the groove and the second sub-opening in the plan view, and wherein the groove, the second sub-opening, and the fourth sub-opening are connected to define a second opening.

At least a portion of the separator may protrude into the second opening.

The pixel-defining layer may include a first pixel-defining layer covering at least a portion of the first electrode, and a second pixel-defining layer covering at least a portion of the separator.

The second electrode may be separated by the separator.

The first insulating layer, the second insulating layer, and the pixel-defining layer may include an organic insulating material.

The display device may further include a connection electrode above the first insulating layer, electrically connected to the transistor, and having a portion exposed by the first opening.

The second electrode may contact the connection electrode in the first opening.

A method of manufacturing a display device according to one or more embodiments of the present disclosure includes forming a transistor above a substrate, forming a first insulating layer above the transistor, forming a second insulating layer defining a first sub-opening above the first insulating layer, forming a pixel-defining layer defining a third sub-opening above the second insulating layer, wherein the third sub-opening is connected to the first sub-opening to define a first opening, and forming a first electrode of a light-emitting element and a separator above the second insulating layer, a portion of the separator protruding into the first opening.

The first electrode and the separator may be formed through a same process.

The first electrode and the separator may be at a same layer.

The first insulating layer may define a groove at a recessed portion of an upper surface of the first insulating layer, wherein the second insulating layer further defines a second sub-opening overlapping the groove in a plan view, wherein the pixel-defining layer further defines a fourth sub-opening overlapping the groove and the second sub-opening in the plan view, and wherein the groove, the second sub-opening, and the fourth sub-opening are connected to define a second opening.

At least a portion of the separator may protrude into the second opening.

The forming of the first insulating layer may include forming a preliminary first insulating layer above the transistor, and removing a portion of the preliminary first insulating layer to form the first insulating layer defining the groove, wherein the forming of the second insulating layer includes forming a preliminary second insulating layer defining a preliminary first sub-opening and a preliminary second sub-opening above the preliminary first insulating layer, and removing a portion of the preliminary second insulating layer in the preliminary first sub-opening and the preliminary second sub-opening to form the second insulating layer defining the first sub-opening and the second sub-opening, wherein the forming of the pixel-defining layer includes forming a preliminary pixel-defining layer covering the separator and defining a preliminary third sub-opening connected to the preliminary first sub-opening, and a preliminary fourth sub-opening connected to the preliminary second sub-opening, above the preliminary second insulating layer, and removing a portion of the preliminary pixel-defining layer in the preliminary third sub-opening and the preliminary fourth sub-opening to form the pixel-defining layer defining the third sub-opening and the fourth sub-opening, and wherein the portion of the preliminary first insulating layer, the portion of the preliminary second insulating layer, and the portion of the preliminary pixel-defining layer are removed through an ashing process.

The method may further include forming an intermediate layer of the light-emitting element above the pixel-defining layer, and forming a second electrode of the light-emitting element above the intermediate layer, wherein the intermediate layer and the second electrode are separated by the separator.

The method may further include forming a connection electrode above the first insulating layer, having a portion exposed by the first opening, and electrically connected to the transistor and the second electrode.

The first insulating layer, the second insulating layer, and the pixel-defining layer may include an organic insulating material.

An electronic device according to one or more embodiments of the present disclosure includes a display device, and a power module configured to supply power to the display device, wherein the display device includes a transistor above a substrate, a first insulating layer above the transistor, a second insulating layer above the first insulating layer and defining a first sub-opening, a light-emitting element above the second insulating layer, electrically connected to the transistor, and including a first electrode, an intermediate layer above the first electrode, and a second electrode above the intermediate layer, a pixel-defining layer above the second insulating layer, covering at least a portion of the first electrode, and defining a third sub-opening overlapping the first sub-opening in a plan view and connected to the first sub-opening to define a first opening, and a separator between the second insulating layer and the pixel-defining layer, and having a portion protruding into the first opening.

In a display device according to embodiments of the present disclosure, the display device may include connection electrodes and a separator. A second electrode arranged above a first electrode may be connected to a pixel-driving circuit through the connecting electrodes, and may be separated by the separator. Accordingly, because a range of change in driving current due to deterioration of a light-emitting element may be reduced, afterimage defect of the display device otherwise due to increased usage time may be reduced, and lifespan of the display device may be improved. In addition, because the separator may be formed through the same process as the first electrode, a separate additional process of forming a component that disconnects an intermediate layer and the second electrode may not be required, and efficiency of a manufacturing process of the display device may be improved.

### BRIEF DESCRIPTION OF THE DRAWINGS

FIG. 1A is a plan view illustrating a display device according to one or more embodiments of the present disclosure.

FIG. 1B is a plan view illustrating a display device according to one or more embodiments of the present disclosure.

FIG. 2A is a circuit diagram illustrating an example of a circuit structure of a pixel included in the display device of FIGS. 1A and 1B.

FIG. 2B is a circuit diagram illustrating an example of a circuit structure of a pixel included in the display device of FIGS. 1A and 1B.

FIG. 3 is a plan view schematically illustrating a partial area of the display device of FIGS. 1A and 1B.

FIG. 4 is an enlarged view illustrating one unit light-emitting area among unit light-emitting areas of FIG. 3.

FIG. 5 is a cross-sectional view taken along the line I-I′ of FIG. 4.

FIGS. 6, 7, and 8 are cross-sectional views illustrating a method of manufacturing a display device according to one or more embodiments of the present disclosure.

FIG. 9 is a block diagram illustrating an electronic device according to one or more embodiments of the present disclosure.

FIG. 10 is a schematic diagram of electronic devices according to various embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

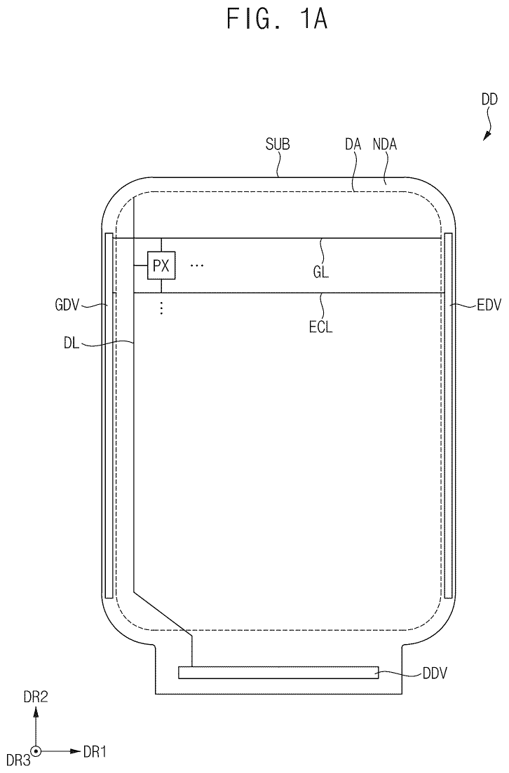

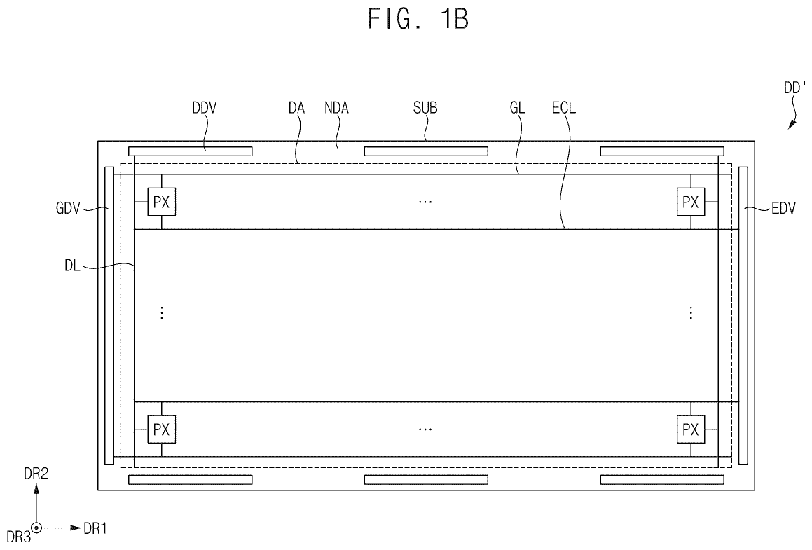

FIG. 1A is a plan view illustrating a display device according to one or more embodiments of the present disclosure. FIG. 1B is a plan view illustrating a display device according to one or more embodiments of the present disclosure.

Referring to FIGS. 1A and 1B, a display device DD or DD′ may be a device activated according to an electrical signal. For example, the display device DD may be a small-sized display device used in a small-sized electronic device, such as a smartphone, a mobile phone, a smart watch, a game console, and a camera. For example, the display device DD′ may be a medium to large-sized display device used in a medium to large-sized electronic device, such as a laptop, a tablet PC, a television, a computer monitor, a vehicle monitor, and an external billboard. FIG. 1A illustrates the display device DD as an example of the small-sized display device, and FIG. 1B illustrates the display device DD′ as an example of the medium to large-sized display device.

The display device DD or DD′ may include a display area DA and a non-display area NDA. The display area DA may be an area that generates light to display an image. The non-display area NDA may be located around the display area DA. For example, the non-display area NDA may surround at least a portion of the display area DA in a plan view. In one or more embodiments, the non-display area NDA may be an area that does not display an image. However, the present disclosure is not limited thereto, and an image may be displayed in at least a portion of the non-display area NDA. For example, a light-emitting element that emits light may be arranged in at least a portion of the non-display area NDA.

The display device DD or DD′ may include a substrate SUB, pixels PX, a gate line GL, a light-emitting control line ECL, a data line DL, a gate driver GDV, a light-emitting driver EDV, and a data driver DDV.

The substrate SUB may form a base of the display device DD or DD'. In one or more embodiments, examples of materials that may be used as the substrate SUB may include glass, quartz, silicon, polymer, or the like. These may be used alone or in combination with each other. The substrate SUB may have a single-layer structure or a multi-layer structure in which a plurality of layers including different materials are stacked.

The pixels PX may be arranged in the display area DA on the substrate SUB. The pixels PX may be electrically connected to the gate line GL, the light-emitting control line ECL, and the data line DL. For example, the pixels PX may be arranged in a matrix form along a first direction DR1 and a second direction DR2 crossing the first direction DR1. Each of the pixels PX may include a pixel-driving circuit and a light-emitting element. The light-emitting element may emit light, and accordingly, an image may be displayed in the display area DA. For example, an image may be displayed in a third direction DR3 crossing each of the first and second directions DR1 and DR2 in the display area DA.

For example, the gate line GL and the light-emitting control line ECL may generally extend in the first direction DR1, and may be arranged along the second direction DR2. The data line DL may generally extend in the second direction DR2, and may be arranged along the first direction DR1. However, the present disclosure is not limited thereto, and the arrangement of the lines may be variously changed depending on embodiments.

The gate driver GDV may be arranged in the non-display area NDA on the substrate SUB. The gate driver GDV may generate a gate signal. The gate driver GDV may output the gate signal to the gate line GL. The gate signal may be applied to the pixels PX through the gate line GL.

The light-emitting driver EDV may be arranged in the non-display area NDA on the substrate SUB. The light-emitting driver EDV may generate a light-emitting control signal. The light-emitting driver EDV may output the light-emitting control signal to the light-emitting control line ECL. The light-emitting control signal may be applied to the pixels PX through the light-emitting control line ECL.

Although FIGS. 1A and 1B illustrate that the gate driver GDV is arranged on a first side of the display device DD or DD′ in the first direction DR1, and the light-emitting driver EDV is arranged on a second side of the display device DD or DD′ in the first direction DR1, the present disclosure is not limited thereto. For example, the gate driver GDV and the light-emitting driver EDV may be arranged together on the first side or the second side of the display device DD or DD'. For another example, the gate driver GDV and the light-emitting driver EDV may be integrally formed.

The data driver DDV may be arranged in the non-display area NDA on the substrate SUB. The data driver DDV may generate a data voltage. The data driver DDV may output the data voltage to the data line DL. The data voltage may be applied to the pixels PX through the data line DL.

In one or more embodiments, the data driver DDV may be mounted on the substrate SUB. However, the present disclosure is not limited thereto, and the data driver DDV may be arranged on a flexible film coupled to the substrate SUB. That is, the display device DD or DD′ may have a structure of a chip on film (COF).

In one or more embodiments, the display device DD′ of FIG. 1B may include a plurality of data drivers DDV. For example, the data drivers DDV may be arranged on both sides of the display device DD′ in the second direction DR2. For example, the data drivers DDV may be arranged along a long side of the display device DD', but the present disclosure is not limited thereto.

The number or arrangement of the gate driver GDV, the light-emitting driver EDV, and the data driver DDV illustrated in FIGS. 1A and 1B is merely an example, and the present disclosure is not limited thereto.

In addition, FIG. 1A illustrates that the display device DD has a substantially rectangular planar shape having a short side extending in the first direction DR1 and a long side extending in the second direction DR2, but the present disclosure is not limited thereto. In addition, FIG. 1B illustrates that the display device DD′ has a rectangular planar shape having a long side extending in the first direction DR1 and a short side extending in the second direction DR2, but the present disclosure is not limited thereto. The planar shape of the display device DD or DD′ may be variously changed depending on embodiments.

The descriptions with reference to following drawings may be equally applied to the display device DD of FIG. 1A and the display device DD′ of FIG. 1B. Therefore, hereinafter, for convenience of description, the expression is unified with the display device DD.

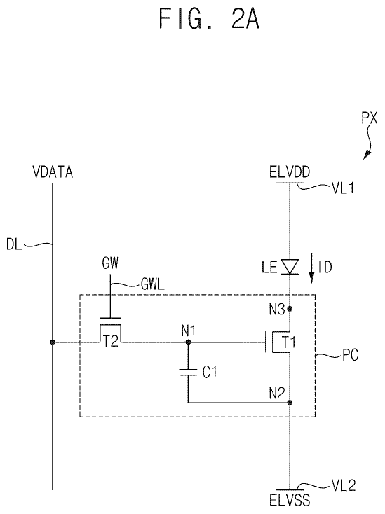

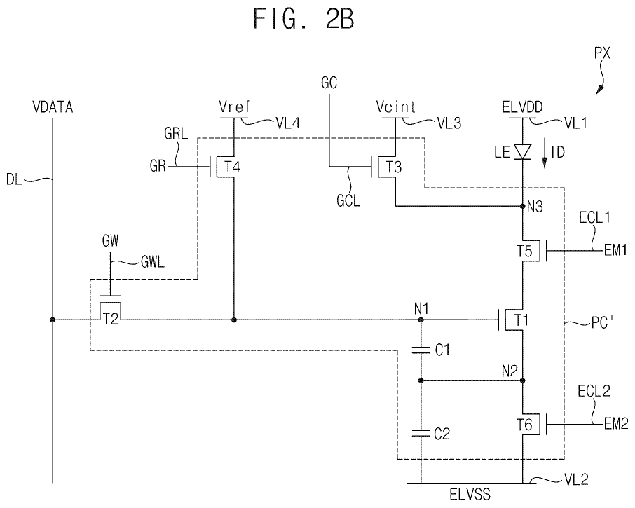

FIG. 2A is a circuit diagram illustrating an example of a circuit structure of a pixel included in the display device of FIGS. 1A and 1B.

Referring to FIG. 2A, the pixel PX may include a light-emitting element LE and a pixel-driving circuit PC. In one or more embodiments, the pixel-driving circuit PC may include a first transistor T1, a second transistor T2, and a first capacitor C1. Although FIG. 2A illustrates that both the first transistor T1 and the second transistor T2 are n-type transistors, the present disclosure is not limited thereto. For example, one of the first transistor T1 or the second transistor T2 may be an n-type transistor, and the other may be a p-type transistor. For example, the first transistor T1 may be an n-type transistor, and the second transistor T2 may be a p-type transistor.

When the pixel PX includes an n-type transistor and a p-type transistor, an active pattern of the n-type transistor may include an oxide semiconductor material, and an active pattern of the p-type transistor may include a silicon semiconductor material. However, the present disclosure is not limited thereto, and each of the active pattern of the n-type transistor and the active pattern of the p-type transistor may include a silicon semiconductor material.

The pixel-driving circuit PC may be connected to a first gate line GWL, a data line DL, a first voltage line VL1, and a second voltage line VL2. The first gate line GWL may transmit a first gate signal GW. The data line DL may transmit a data voltage VDATA. The first voltage line VL1 may transmit a first power voltage ELVDD having a relatively high voltage level. The second voltage line VL2 may transmit a second power voltage ELVSS having a relatively low voltage level. The first power voltage ELVDD may have a higher voltage level than the second power voltage ELVSS.

The first transistor T1 may include a gate terminal, a first terminal, and a second terminal. In one or more embodiments, the first terminal of the first transistor T1 may be a source, and the second terminal of the first transistor T1 may be a drain. The gate terminal of the first transistor T1 may be connected to a first node N1. The first terminal of the first transistor T1 may be connected to a second node N2. The second terminal of the first transistor T1 may be connected to a third node N3. The second terminal of the first transistor T1 may be connected to the light-emitting element LE. The first transistor T1 may provide a driving current ID to the light-emitting element LE.

The second transistor T2 may include a gate terminal, a first terminal, and a second terminal. In one or more embodiments, the first terminal of the second transistor T2 may be a source, and the second terminal of the second transistor T2 may be a drain. However, the present disclosure is not limited thereto, and the first terminal of the second transistor T2 may be a drain, and the second terminal of the second transistor T2 may be a source. The gate terminal of the second transistor T2 may be connected to the first gate line GWL. The first terminal of the second transistor T2 may be connected to the data line DL. The second terminal of the second transistor T2 may be connected to the first node N1.

The gate terminal of the second transistor T2 may receive the first gate signal GW through a first gate line GWL. The second transistor T2 may be turned on or off in response to the first gate signal GW. The first terminal of the second transistor T2 may receive the data voltage VDATA through the data line DL. During a period in which the second transistor T2 is turned on, the second terminal of the second transistor T2 may provide the data voltage VDATA to the first node N1.

The first capacitor C1 may include a first terminal and a second terminal. The first terminal of the first capacitor C1 may be connected to the first node N1. The second terminal of the first capacitor C1 may be connected to the second node N2. The first capacitor C1 may be charged and discharged according to the data voltage VDATA transmitted to the first node N1.

The light-emitting element LE may include a first terminal and a second terminal. The first terminal of the light-emitting element LE may be connected to the third node N3. The second terminal of the light-emitting element LE may be connected to the first voltage line VL1. The first terminal of the light-emitting element LE may be a cathode, and the second terminal of the light-emitting element LE may be an anode. The first terminal (e.g., the cathode) of the light-emitting element LE may be connected to the second terminal of the first transistor T1.

FIG. 2B is a circuit diagram illustrating an example of a circuit structure of a pixel included in the display device of FIGS. 1A and 1B.

Referring to FIG. 2B, the pixel PX may include a light-emitting element LE and a pixel-driving circuit PC'. In one or more embodiments, the pixel-driving circuit PC′ may include first, second, third, fourth, fifth, and sixth transistors T1, T2, T3, T4, T5, and T6, a first capacitor C1, and a second capacitor C2. Although FIG. 2B illustrates that all of the first, second, third, fourth, fifth, and sixth transistors T1, T2, T3, T4, T5, and T6 are n-type transistors, the present disclosure is not limited thereto. For example, some of the first, second, third, fourth, fifth, and sixth transistors T1, T2, T3, T4, T5, and T6 may be n-type transistors, and the other thereof may be p-type transistors. For example, the first transistor T1 may be an n-type transistor, some of the second, third, fourth, fifth, and sixth transistors T2, T3, T4, T5, and T6 may be n-type transistors, and the other thereof may be p-type transistors.

The pixel-driving circuit PC′ may be connected to first, second, and third gate lines GWL, GCL, and GRL, a data line DL, first, second, third, and fourth voltage lines VL1, VL2, VL3, and VL4, and first and second light-emitting control lines ECL1 and ECL2. The first gate line GWL may transmit a first gate signal GW. The second gate line GCL may transmit a second gate signal GC. The third gate line GRL may transmit a third gate signal GR. The data line DL may transmit a data voltage VDATA. The first voltage line VL1 may transmit a first power voltage ELVDD having a relatively high voltage level. The second voltage line VL2 may transmit a second power voltage ELVSS having a relatively low voltage level. The first power voltage ELVDD may have a higher voltage level than the second power voltage ELVSS. The third voltage line VL3 may transmit a first initialization voltage Vcint. The fourth voltage line VL4 may transmit a reference voltage Vref. The reference voltage Vref may have a lower voltage level than the first power voltage ELVDD.

The first transistor T1 may include a gate terminal, a first terminal, and a second terminal. The gate terminal of the first transistor T1 may be connected to a first node N1. The first terminal of the first transistor T1 may be connected to a second node N2. The second terminal of the first transistor T1 may be connected to the fifth transistor T5. The second terminal of the first transistor T1 may be connected to the light-emitting element LE through the fifth transistor T5. The first transistor T1 may provide a driving current ID to the light-emitting element LE.

The second transistor T2 may include a gate terminal, a first terminal, and a second terminal. In one or more embodiments, the first terminal of the second transistor T2 may be a source, and the second terminal of the second transistor T2 may be a drain. However, the present disclosure is not limited thereto, and the first terminal of the second transistor T2 may be a drain, and the second terminal of the second transistor T2 may be a source. The gate terminal of the second transistor T2 may be connected to the first gate line GWL. The first terminal of the second transistor T2 may be connected to the data line DL. The second terminal of the second transistor T2 may be connected to the first node N1.

The gate terminal of the second transistor T2 may receive the first gate signal GW through the first gate line GWL. The second transistor T2 may be turned on or off in response to the first gate signal GW. The first terminal of the second transistor T2 may receive the data voltage VDATA through the data line DL. During a period in which the second transistor T2 is turned on, the second terminal of the second transistor T2 may provide the data voltage VDATA to the first node N1.

The third transistor T3 may include a gate terminal, a first terminal, and a second terminal. In one or more embodiments, the first terminal of the third transistor T3 may be a source, and the second terminal of the third transistor T3 may be a drain. However, the present disclosure is not limited thereto, and the first terminal of the third transistor T3 may be a drain, and the second terminal of the third transistor T3 may be a source. The gate terminal of the third transistor T3 may be connected to the second gate line GCL. The first terminal of the third transistor T3 may be connected to a third node N3. The second terminal of the third transistor T3 may be connected to the third voltage line VL3.

The gate terminal of the third transistor T3 may receive the second gate signal GC through the second gate line GCL. The third transistor T3 may be turned on or off in response to the second gate signal GC. During a period in which the third transistor T3 is turned on, the third transistor T3 may provide the first initialization voltage Vcint to the third node N3. The third transistor T3 may provide the first initialization voltage Vcint to a first terminal of the light-emitting element LE in response to the second gate signal GC to initialize a voltage of the first terminal of the light-emitting element LE.

The fourth transistor T4 may include a gate terminal, a first terminal, and a second terminal. In one or more embodiments, the first terminal of the fourth transistor T4 may be a source, and the second terminal of the fourth transistor T4 may be a drain. However, the present disclosure is not limited thereto, and the first terminal of the fourth transistor T4 may be a drain, and the second terminal of the fourth transistor T4 may be a source. The gate terminal of the fourth transistor T4 may be connected to the third gate line GRL. The first terminal of the fourth transistor T4 may be connected to the first node N1. The second terminal of the fourth transistor T4 may be connected to the fourth voltage line VL4.

The gate terminal of the fourth transistor T4 may receive the third gate signal GR through the third gate line GRL. The fourth transistor T4 may be turned on or off in response to the third gate signal GR. During a period in which the fourth transistor T4 is turned on, the fourth transistor T4 may provide the reference voltage Vref to the first node N1.

The fifth transistor T5 may include a gate terminal, a first terminal, and a second terminal. In one or more embodiments, the first terminal of the fifth transistor T5 may be a source, and the second terminal of the fifth transistor T5 may be a drain. However, the present disclosure is not limited thereto, and the first terminal of the fifth transistor T5 may be a drain, and the second terminal of the fifth transistor T5 may be a source. The gate terminal of the fifth transistor T5 may be connected to the first light-emitting control line ECL1. The first terminal of the fifth transistor T5 may be connected to the second terminal of the first transistor T1. The second terminal of the fifth transistor T5 may be connected to the third node N3. The second terminal of the fifth transistor T5 may be connected to the light-emitting element LE.

The gate terminal of the fifth transistor T5 may receive the first light-emitting control signal EM1 through the first light-emitting control line ECL1. The fifth transistor T5 may be turned on or off in response to the first light-emitting control signal EM1. During a period in which the fifth transistor T5 is turned on, the fifth transistor T5 may electrically connect the first transistor T1 and the light-emitting element LE. The fifth transistor T5 may electrically connect the second terminal of the first transistor T1 and the first terminal of the light-emitting element LE in response to the first light-emitting control signal EM1.

The sixth transistor T6 may include a gate terminal, a first terminal, and a second terminal. In one or more embodiments, the first terminal of the sixth transistor T6 may be a source, and the second terminal of the sixth transistor T6 may be a drain. However, the present disclosure is not limited thereto, and the first terminal of the sixth transistor T6 may be a drain, and the second terminal of the sixth transistor T6 may be a source. The gate terminal of the sixth transistor T6 may be connected to the second light-emitting control line ECL2. The first terminal of the sixth transistor T6 may be connected to the second voltage line VL2. The second terminal of the sixth transistor T6 may be connected to the second node N2.

The gate terminal of the sixth transistor T6 may receive the second light-emitting control signal EM2 through the second light-emitting control line ECL2. The sixth transistor T6 may be turned on or off in response to the second light-emitting control signal EM2. During a period in which the sixth transistor T6 is turned on, the sixth transistor T6 may provide the second power voltage ELVSS to the second node N2.

Although FIG. 2B illustrates that the fifth transistor T5 and the sixth transistor T6 are independently driven by different light-emitting control signals, the present disclosure is not limited thereto. For example, the first light-emitting control signal EM1 and the second light-emitting control signal EM2 may be provided as substantially a single light-emitting control signal, and the fifth transistor T5 and the sixth transistor T6 may be turned on or off concurrently or substantially simultaneously. In this case, the first light-emitting control line ECL1 and the second light-emitting control line ECL2 may be provided as substantially a single light-emitting control line.

The first capacitor C1 may include a first terminal and a second terminal. The first terminal of the first capacitor C1 may be connected to the first node N1. The second terminal of the first capacitor C1 may be connected to the second node N2. The first capacitor C1 may be charged and discharged according to the data voltage VDATA transmitted to the first node N1.

The second capacitor C2 may include a first terminal and a second terminal. The first terminal of the second capacitor C2 may be connected to the second node N2. The second terminal of the second capacitor C2 may be connected to the second voltage line VL2. For example, the second capacitor C2 may be connected to the first capacitor C1 in series. The data voltage VDATA may be transmitted to the first node N1, and the data voltage VDATA may be voltage-divided and transmitted to the second node N2 due to the serial connection of the first capacitor C1 and the second capacitor C2. Because the first transistor T1 generates the driving current ID based on a voltage of the first node N1 and a voltage of the second node N2, data range may be extended.

The light-emitting element LE may include the first terminal and a second terminal. The first terminal of the light-emitting element LE may be connected to the third node N3. The second terminal of the light-emitting element LE may be connected to the first voltage line VL1. The first terminal of the light-emitting element LE may be a cathode, and the second terminal of the light-emitting element LE may be an anode. The first terminal (e.g., the cathode) of the light-emitting element LE may be connected to the second terminal of the first transistor T1 through the fifth transistor T5.

As illustrated in FIGS. 2A and 2B, according to the present disclosure, the first terminal of the light-emitting element LE may be connected to the second terminal of the first transistor T1, and the second terminal of the light-emitting element LE may receive the first power voltage ELVDD through the first voltage line VL1. That is, a potential of the first terminal of the light-emitting element LE may be controlled by being electrically connected to the first transistor T1.

Because the first voltage line VL1 provides the first power voltage ELVDD of a relatively high voltage level, and the second voltage line VL2 provides the second power voltage ELVSS of a relatively low voltage level, the second terminal of the first transistor T1 may be a drain when the first transistor T1 is an n-type transistor. That is, according to the present disclosure, the cathode of the light-emitting element LE may be connected to the drain of the first transistor T1.

When the first transistor T1 is an n-type transistor, if the anode of the light-emitting element LE is connected to the source of the first transistor T1, a source voltage of the first transistor T1 may shift due to deterioration of the light-emitting element LE, and a gate-source voltage (Vgs) of the first transistor T1 may change. Accordingly, a range of change in the driving current ID may increase, causing an afterimage defect and reducing a lifespan of the display device.

According to the present disclosure, the anode (e.g., the second terminal) of the light-emitting element LE may receive the first power voltage ELVDD, and the cathode (e.g., the first terminal) of the light-emitting element LE may be connected to the drain of the first transistor T1. Accordingly, the gate-source voltage of the first transistor T1 may not change even when the light-emitting element LE deteriorates, and the range of change in the driving current ID due to the deterioration of the light-emitting element LE may be reduced. Accordingly, the afterimage defect of the display device DD due to an increase in usage time may be reduced, and the lifespan of the display device DD may be improved.

The circuit structure of the pixel illustrated in FIGS. 2A and 2B (e.g., the number or arrangement relationship of transistors, the number or arrangement relationship of capacitors, or the like) is merely an example, and may be variously changed depending on embodiments.

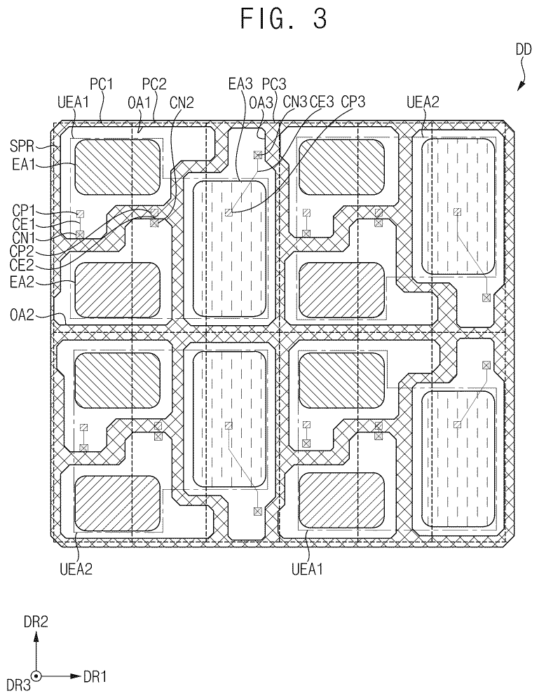

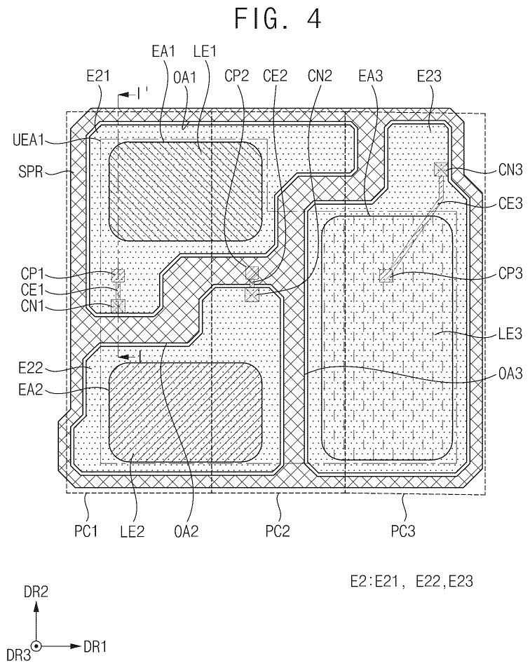

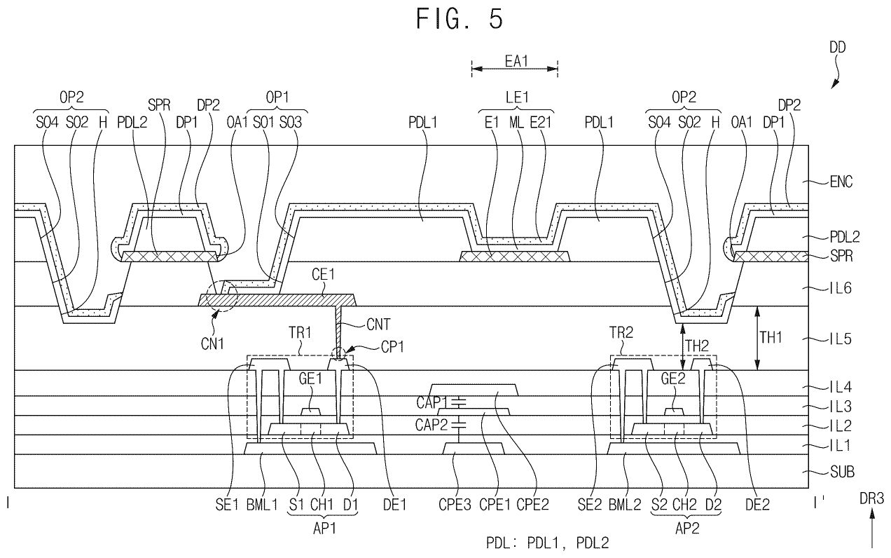

FIG. 3 is a plan view schematically illustrating a partial area of the display device of FIGS. 1A and 1B. FIG. 4 is an enlarged view illustrating one unit light-emitting area among unit light-emitting areas of FIG. 3. FIG. 5 is a cross-sectional view taken along the line I-I′ of FIG. 4.

FIG. 3 illustrates an area in which a total of four unit light-emitting areas UEA1 and UEA2 forming a matrix of two rows and two columns are arranged, and FIG. 4 illustrates an enlarged first unit light-emitting area UEA1 among the unit light-emitting areas UEA1 and UEA2. For convenience of description, some of components illustrated in FIG. 5 are omitted or emphasized in FIGS. 3 and 4. In addition, an electrode layer E2 among components illustrated in FIG. 4 is omitted in FIG. 3.

Referring to FIGS. 3 and 4, the display device DD may include first, second, and third pixel-driving circuits PC1, PC2, and PC3, first, second, and third light-emitting elements LE1, LE2, and LE3, first, second, and third connection electrodes CE1, CE2, and CE3, and a separator SPR.

Each of the first, second, and third pixel-driving circuits PC1, PC2, and PC3 may correspond to at least one of the pixel-driving circuits PC or PC′ described with reference to FIGS. 2A and 2B. That is, each of the first, second, and third pixel-driving circuits PC1, PC2, and PC3 may include at least one transistor and at least one capacitor. For example, each of the first, second, and third pixel-driving circuits PC1, PC2, and PC3 may include a first transistor TR1, a second transistor TR2, a first capacitor CAP1, and a second capacitor CAP2 illustrated in FIG. 5.

In this case, the first transistor TR1 of FIG. 5 may be a transistor connected to a light-emitting element through a connection electrode. For example, when the first, second, and third pixel-driving circuits PC1, PC2, and PC3 are the pixel-driving circuit unit PC of FIG. 2A, the first transistor TR1 may be the first transistor T1 of FIG. 2A, and the second transistor TR2 may be the second transistor T2 of FIG. 2A. For example, when the first, second, and third pixel-driving circuits PC1, PC2, and PC3 are the pixel-driving circuit PC′ of FIG. 2B, the first transistor TR1 may be the fifth transistor T5 of FIG. 2B, and the second transistor TR2 may be one of the first, second, third, fourth, or sixth transistors T1, T2, T3, T4, or T6 of FIG. 2B. However, the present disclosure is not limited thereto.

For example, the first capacitor CAP1 of FIG. 5 may correspond to the first capacitor C1 of FIGS. 2A and 2B, and the second capacitor CAP2 of FIG. 5 may correspond to the second capacitor C2 of FIG. 2B. When the first, second, and third pixel-driving circuits PC1, PC2, and PC3 are the pixel-driving circuit PC of FIG. 2A, the second capacitor CAP2 may be omitted. However, the present disclosure is not limited thereto, and for example, the first capacitor CAP1 may correspond to the second capacitor C2 of FIGS. 2A and 2B, and the second capacitor CAP2 may correspond to the first capacitor C1 of FIG. 2B. When the first, second, and third pixel-driving circuits PC1, PC2, and PC3 are the pixel-driving circuit PC of FIG. 2A, the first capacitor CAP1 may be omitted.

Components of the first transistor TR1, the second transistor TR2, the first capacitor CAP1, and the second capacitor CAP2 will be described later in more detail with reference to FIG. 5.

Although FIGS. 3 and 4 illustrate that the first, second, and third pixel-driving circuits PC1, PC2, and PC3 are sequentially arranged along the first direction DR1 in a rectangular planar shape, the present disclosure is not limited thereto. The shapes and arrangements of the first, second, and third pixel-driving circuits PC1, PC2, and PC3 may be variously changed depending on embodiments.

Each of the first, second, and third light-emitting elements LE1, LE2, and LE3 may correspond to the light-emitting element LE described with reference to FIGS. 2A and 2B. For example, each of the first, second, and third light-emitting elements LE1, LE2, and LE3 may include a first electrode (e.g., a first electrode E1 of FIG. 5), an intermediate layer (e.g., an intermediate layer ML of FIG. 5) arranged on the first electrode, and the electrode layer E2 arranged on the intermediate layer. In one or more embodiments, the first electrode may function as the second terminal of the light-emitting element LE of FIGS. 2A and 2B, and the electrode layer E2 may function as the first terminal of the light-emitting element LE of FIGS. 2A and 2B.

In one or more embodiments, the electrode layer E2 may be separated (or disconnected) into second electrodes E21, E22, and E23 by the separator SPR. The electrode layer E2 may be separated (or disconnected) into a second electrode E21 of the first light-emitting element LE1, a second electrode E22 of the second light-emitting element LE2, and a second electrode E23 of the third light-emitting element LE3. The second electrodes E21, E22, and E23 may be electrically independent of each other. This will be described in more detail later.

The first, second, and third light-emitting elements LE1, LE2, and LE3 may emit light of different respective colors. For example, the first light-emitting element LE1 may emit red light, the second light-emitting element LE2 may emit green light, and the third light-emitting element LE3 may emit blue light, but the present disclosure is not limited thereto.

In one or more embodiments, the display device DD may include a first unit light-emitting area UEA1 and a second unit light-emitting area UEA2. The first unit light-emitting area UEA1 and the second unit light-emitting area UEA2 may be defined in a matrix form along the first and second directions DR1 and DR2. Although FIG. 3 illustrates four unit light-emitting areas, the unit light-emitting areas in the display area DA (see FIGS. 1A and 1B) may be defined in a matrix form along the first and second directions DR1 and DR2.

The first, second, and third light-emitting elements LE1, LE2, and LE3 adjacent to each other may be arranged in each of the first and second unit light-emitting areas UEA1 and UEA2. For example, first, second, and third light-emitting areas EA1, EA2, and EA3 adjacent to each other may be defined in each of the first and second unit light-emitting areas UEA1 and UEA2, and the first, second, and third light-emitting elements LE1, LE2, and LE3 may be arranged in the first, second, and third light-emitting areas EA1, EA2, and EA3, respectively. Each of the first, second, and third light-emitting areas EA1, EA2, and EA3 may be an area in which light is emitted by the light-emitting element. The first, second, and third light-emitting areas EA1, EA2, and EA3 may be defined by pixel openings of a pixel-defining layer (e.g., a pixel-defining layer PDL of FIG. 5).

For example, the first light-emitting element LE1 may be arranged in the first light-emitting area EA1, and the first light-emitting area EA1 may be an area in which light is emitted by the first light-emitting element LE1. The second light-emitting element LE2 may be arranged in the second light-emitting area EA2, and the second light-emitting area EA2 may be an area in which light is emitted by the second light-emitting element LE2. The third light-emitting element LE3 may be arranged in the third light-emitting area EA3, and the third light-emitting area EA3 may be an area in which light is emitted by the third light-emitting element LE3.

In one or more embodiments, the first unit light-emitting area UEA1 and the second unit light-emitting area UEA2 may be distinguished based on an arrangement relationship between the first, second, and third light-emitting elements LE1, LE2, and LE3 (or an arrangement relationship between the first, second, and third light-emitting areas EA1, EA2, and EA3). That is, the arrangement relationship between the first, second, and third light-emitting areas LE1, LE2, LE3 (or the first, second, and third light-emitting areas EA1, EA2, and EA3) in each first unit light-emitting area UEA1 may be the same, and the arrangement relationship between the first, second, and third light-emitting elements LE1, LE2, and LE3 (or the first, second, and third light-emitting areas EA1, EA2, and EA3) in each second unit light-emitting area UEA2 may be the same.

As illustrated in FIG. 3, in one or more embodiments, the first unit light-emitting area UEA1 and the second unit light-emitting area UEA2 may be alternately defined along the first direction DR1 (e.g., a row direction) and the second direction DR2 (e.g., a column direction). However, the present disclosure is not limited thereto, and the number of different unit light-emitting areas included in the display device DD or the arrangement relationship between the unit light-emitting areas may be variously changed depending on embodiments.

Although FIGS. 3 and 4 illustrate that the first, second, and third light-emitting areas EA1, EA2, and EA3 are arranged in an S-stripe type, the present disclosure is not limited thereto, and the arrangement of the first, second, and third light-emitting areas EA1, EA2, and EA3 may be variously changed depending on embodiments.

The first, second, and third light-emitting elements LE1, LE2, and LE3 may be connected to one of the first, second, or third pixel-driving circuits PC1, PC2, or PC3, respectively. The first light-emitting element LE1 may be connected to the first pixel-driving circuit PC1, the second light-emitting element LE2 may be connected to the second pixel-driving circuit PC2, and the third light-emitting element LE3 may be connected to the third pixel-driving circuit PC3. Accordingly, the first pixel-driving circuit PC1 and the first light-emitting element LE1 may define one pixel, the second pixel-driving circuit PC2 and the second light-emitting element LE2 may define one pixel, and the third pixel-driving circuit PC3 and the third light-emitting element LE3 may define one pixel.

Hereinafter, a connection relationship between the first, second, and third light-emitting elements LE1, LE2, and LE3 and the first, second, and third pixel-driving circuits PC1, PC2, and PC3 will be described in more detail, focusing on the first unit light-emitting area UEA1 of FIG. 4. The following description of the connection relationship between the first, second, and third light-emitting elements LE1, LE2, and LE3 and the first, second, and third pixel-driving circuits PC1, PC2, and PC3 may be equally applied to all unit light-emitting areas.

As described above, the display device DD may include the first, second, and third connection electrodes CE1, CE2, and CE3. In one or more embodiments, the first connection electrode CE1 may connect the first light-emitting element LE1 and the first pixel-driving circuit PC1, the second connection electrode CE2 may connect the second light-emitting element LE2 and the second pixel-driving circuit PC2, and the third connection electrode CE3 may connect the third light-emitting element LE3 and the third pixel-driving circuit PC3.

The first, second, and third connection electrodes CE1, CE2, and CE3 may include a conductive material, such as a metal, an alloy, a conductive metal nitride, a conductive metal oxide, a transparent conductive oxide, or the like. Examples of the conductive materials may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, an alloy containing silver, an alloy containing copper, an alloy containing molybdenum, aluminum nitride (AlN), tungsten nitride (WN), titanium nitride (TiN), chromium nitride (CrN), tantalum nitride (TaN), indium gallium zinc oxide (IGZO), indium tin zinc oxide (ITZO), indium tin oxide (ITO), indium zinc oxide (IZO), indium gallium oxide (IGO), zinc oxide (ZnO), indium oxide (InO), tin oxide (SnO), gallium oxide (GaO), aluminum zinc oxide (AZO), or the like. These may be used alone or in combination with each other. The first, second, and third connection electrodes CE1, CE2, and CE3 may have a single-layer structure or a multi-layer structure in which a plurality of conductive layers are stacked.

The first connection electrode CE1 may include a first circuit connection portion CP1 and a first light-emitting connection portion CN1.

The first circuit connection portion CP1 may be a portion of the first connection electrode CE1 that is connected to the first pixel-driving circuit PC1. For example, the first circuit connection portion CP1 may be a portion of the first connection electrode CE1 that is connected to a first transistor (e.g., a first transistor TR1 of FIG. 5) of the first pixel-driving circuit PC1. A position of the first circuit connection portion CP1 may correspond to a position of the first transistor of the first pixel-driving circuit PC1. The position of the first circuit connection portion CP1 may correspond to a position of a contact hole (e.g., a contact hole CNT of FIG. 5) that exposes the first transistor and penetrates a fifth insulating layer (e.g., a fifth insulating layer IL5 of FIG. 5, which may be referred to as a first insulating layer in the claims).

The first light-emitting connection portion CN1 may be a portion of the first connection electrode CE1 that is connected to the second electrode E21 of the first light-emitting element LE1. For example, the first light-emitting connection portion CN1 may be a portion of the first connection electrode CE1 exposed from the pixel-defining layer (e.g., a pixel-defining layer PDL of FIG. 5) and a sixth insulating layer (e.g., a sixth insulating layer IL6 of FIG. 5, which may be referred to as a second insulating layer in the claims) to contact the second electrode E21. A position of the first light-emitting connection portion CN1 may correspond to a position of a first opening (e.g., a first opening OP1 of FIG. 5) that exposes the first connection electrode CE1 and penetrates the pixel-defining layer and the sixth insulating layer.

The second electrode E21 of the first light-emitting element LE1 may be connected to the first connection electrode CE1. For example, the second electrode E21 of the first light-emitting element LE1 may contact the first connection electrode CE1. The second electrode E21 of the first light-emitting element LE1 may be connected to the first pixel-driving circuit PC1 through the first connection electrode CE1.

In one or more embodiments, the first light-emitting connection portion CN1 may be arranged at a position that does not overlap the first light-emitting area EA1 in a plan view. For example, in a plan view, the first light-emitting connection portion CN1 may be arranged between the first light-emitting area EA1 and the separator SPR. For example, the second electrode E21 of the first light-emitting element LE1 may have a protruding portion protruding from the first light-emitting area EA1 to a position that does not overlap the first light-emitting area EA1 in a plan view, and the second electrode E21 of the first light-emitting element LE1 and the first connection electrode CE1 may contact each other at a position that does not overlap the first light-emitting area EA1. Accordingly, the second electrode E21 of the first light-emitting element LE1 and the first pixel-driving circuit PC1 may be electrically connected through the first connection electrode CE1 without reducing a light-emitting area of the first light-emitting area EA1.

The second connection electrode CE2 may include a second circuit connection portion CP2 and a second light-emitting connection portion CN2.

The second circuit connection portion CP2 may be a portion of the second connection electrode CE2 that is connected to the second pixel-driving circuit PC2. For example, the second circuit connection portion CP2 may be a portion of the second connection electrode CE2 that is connected to a first transistor (e.g., a first transistor TR1 of FIG. 5) of the second pixel-driving circuit PC2. A position of the second circuit connection portion CP2 may correspond to a position of the first transistor of the second pixel-driving circuit PC2. The position of the second circuit connection portion CP2 may correspond to a position of a contact hole that exposes the first transistor of the second pixel-driving circuit PC2 and that penetrates the fifth insulating layer (e.g., a fifth insulating layer IL5 of FIG. 5, which may be referred to as a first insulating layer in the claims).

The second light-emitting connection portion CN2 may be a portion of the second connection electrode CE2 that is connected to the second electrode E22 of the second light-emitting element LE2. For example, the second light-emitting connection portion CN2 may be a portion of the second connection electrode CE2 that is exposed from the pixel-defining layer (e.g., a pixel-defining layer PDL of FIG. 5) and the sixth insulating layer (e.g., a sixth insulating layer IL6 of FIG. 5, which may be referred to as a second insulating layer in the claims) to contact the second electrode E22. A position of the second light-emitting connection portion CN2 may correspond to a position of a first opening (e.g., a first opening OP1 of FIG. 5) that exposes the second connection electrode CE2 and that penetrates the pixel-defining layer and the sixth insulating layer.

The second electrode E22 of the second light-emitting element LE2 may be connected to the second connection electrode CE2. For example, the second electrode E22 of the second light-emitting element LE2 may contact the second connection electrode CE2. The second electrode E22 of the second light-emitting element LE2 may be connected to the second pixel-driving circuit PC2 through the second connection electrode CE2.

In one or more embodiments, the second light-emitting connection portion CN2 may be arranged at a position that does not overlap the second light-emitting area EA2 in a plan view. For example, in a plan view, the second light-emitting connection portion CN2 may be arranged between the second light-emitting area EA2 and the separator SPR. For example, the second electrode E22 of the second light-emitting element LE2 may have a protruding portion protruding from the second light-emitting area EA2 to a position that does not overlap the second light-emitting area EA2 in a plan view, and the second electrode E22 of the second light-emitting element LE2 and the second connection electrode CE2 may contact each other at a position that does not overlap the second light-emitting area EA2. Accordingly, the second electrode E22 of the second light-emitting element LE2 and the second pixel-driving circuit PC2 may be electrically connected through the second connection electrode CE2 without reducing a light-emitting area of the second light-emitting area EA2.

The third connection electrode CE3 may include a third circuit connection portion CP3 and a third light-emitting connection portion CN3.

The third circuit connection portion CP3 may be a portion of the third connection electrode CE3 that is connected to the third pixel-driving circuit PC3. For example, the third circuit connection portion CP3 may be a portion of the third connection electrode CE3 that is connected to a first transistor (e.g., a first transistor TR1 of FIG. 5) of the third pixel-driving circuit PC3. A position of the third circuit connection portion CP3 may correspond to a position of the first transistor of the third pixel-driving circuit PC3. The position of the third circuit connection portion CP3 may correspond to a position of a contact hole that exposes the first transistor of the third pixel-driving circuit PC3 and penetrates the fifth insulating layer (e.g., a fifth insulating layer IL5 of FIG. 5, which may be referred to as a first insulating layer in the claims).

The third light-emitting connection portion CN3 may be a portion of the third connection electrode CE3 that is connected to the second electrode E23 of the third light-emitting element LE3. For example, the third light-emitting connection portion CN3 may be a portion of the third connection electrode CE3 that is exposed from the pixel-defining layer (e.g., a pixel-defining layer PDL of FIG. 5) and the sixth insulating layer (e.g., a sixth insulating layer IL6 of FIG. 5, which may be referred to as a second insulating layer in the claims) to contact the second electrode E23. A position of the third light-emitting connection portion CN3 may correspond to a position of a first opening (e.g., a first opening OP1 of FIG. 5) that exposes the third connection electrode CE3 and that penetrates the pixel-defining layer and the sixth insulating layer.

The second electrode E23 of the third light-emitting element LE3 may be connected to the third connection electrode CE3. For example, the second electrode E23 of the third light-emitting element LE3 may contact the third connection electrode CE3. The second electrode E23 of the third light-emitting element LE3 may be connected to the third pixel-driving circuit PC3 through the third connection electrode CE3.

In one or more embodiments, the third light-emitting connection portion CN3 may be arranged at a position that does not overlap the third light-emitting area EA3 in a plan view. For example, in a plan view, the third light-emitting connection portion CN3 may be arranged between the third light-emitting area EA3 and the separator SPR. For example, the second electrode E23 of the third light-emitting element LE3 may have a protruding portion protruding from the third light-emitting area EA3 to a position that does not overlap the third light-emitting area EA3 in a plan view, and the second electrode E23 of the third light-emitting element LE3 and the third connection electrode CE3 may contact each other at a position that does not overlap the third light-emitting area EA3. Accordingly, the second electrode E23 of the third light-emitting element LE3 and the third pixel-driving circuit PC3 may be electrically connected through the third connection electrode CE3 without reducing a light-emitting area of the third light-emitting area EA3.

In one or more embodiments, the first connection electrode CE1, the second connection electrode CE2, and the third connection electrode CE3 may be spaced apart from each other in a plan view. The first connection electrode CE1, the second connection electrode CE2, and the third connection electrode CE3 may be different electrodes that are distinguished from each other.

As described above, the display device DD may include the separator SPR. The separator SPR may be arranged on the sixth insulating layer, which may be referred to as a second insulating layer in the claims. In one or more embodiments, the separator SPR may include a conductive material, such as a metal, an alloy, a conductive metal oxide, a conductive metal nitride, a transparent conductive oxide, or the like.

The electrode layer E2 may be separated (or disconnected) into the second electrodes E21, E22, and E23 by the separator SPR. That is, the second electrode E21 of the first light-emitting element LE1, the second electrode E22 of the second light-emitting element LE2, and the second electrode E23 of the third light-emitting element LE3 may be electrically independent of each other by the separator SPR.

The separator SPR may define first, second, and third open areas OA1, OA2, and OA3 corresponding to the second electrodes E21, E22, and E23, respectively. For example, the separator SPR may have a mesh structure surrounding the second electrodes E21, E22, and E23 in a plan view. The second electrode E21 of the first light-emitting element LE1 may be arranged in the first open area OA1 of the separator SPR, the second electrode E22 of the second light-emitting element LE2 may be arranged in the second open area OA2 of the separator SPR, and the second electrode E23 of the third light-emitting element LE3 may be arranged in the third open area OA3 of the separator SPR.

For example, a planar shape of the first open area OA1 may be substantially the same as a planar shape of the second electrode E21 of the first light-emitting element LE1, a planar shape of the second open area OA2 may be substantially the same as a planar shape of the second electrode E22 of the second light-emitting element LE2, and a planar shape of the third open area OA3 may be substantially the same as a planar shape of the second electrode E23 of the third light-emitting element LE3.

Hereinafter, a cross-sectional structure of the display device DD will be described in more detail with reference to FIG. 5, focusing on the first light-emitting area EA1. The following description of the cross-sectional structure of the display device DD may be equally applied to all light-emitting areas.

Referring further to FIG. 5, the display device DD may include a substrate SUB, a first lower conductive layer BML1, a second lower conductive layer BML2, a first transistor TR1, a second transistor TR2, a first capacitor CAP1, a second capacitor CAP2, the first connection electrode CE1, first, second, third, fourth, fifth, and sixth insulating layers IL1, IL2, IL3, IL4, IL5, and IL6, the separator SPR, a pixel-defining layer PDL, the first light-emitting element LE1, a first dummy layer DP1, a second dummy layer DP2, and an encapsulation layer ENC.

The first transistor TR1 may include a first active pattern AP1, a first gate electrode GE1, a first contact electrode SE1, and a second contact electrode DE1. The second transistor TR2 may include a second active pattern AP2, a second gate electrode GE2, a third contact electrode SE2, and a fourth contact electrode DE2. The first capacitor CAP1 may include a first capacitor electrode CPE1 and a second capacitor electrode CPE2. The second capacitor CAP2 may include the first capacitor electrode CPE1 and a third capacitor electrode CPE3. The first light-emitting element LE1 may include a first electrode E1, an intermediate layer ML, and the second electrode E21.

The first transistor TR1, the second transistor TR2, the first capacitor CAP1, and the second capacitor CAP2 may be included in the first pixel-driving circuit PC1.

The first lower conductive layer BML1, the second lower conductive layer BML2, and the third capacitor electrode CPE3 may be arranged on the substrate SUB. The first lower conductive layer BML1, the second lower conductive layer BML2, and the third capacitor electrode CPE3 may include a conductive material, such as a metal, an alloy, a conductive metal oxide, a conductive metal nitride, a transparent conductive oxide, or the like.

The first insulating layer IL1 may be arranged on the substrate SUB, and may cover the first lower conductive layer BML1, the second lower conductive layer BML2, and the third capacitor electrode CPE3. The first insulating layer IL1 may reduce or prevent metal atoms or impurities diffusing from the substrate SUB into the first active pattern AP1 or the second active pattern AP2. The first insulating layer IL1 may include an insulating material. Examples of the insulating material may include silicon oxide, silicon nitride, silicon oxynitride, or the like. These may be used alone or in combination with each other.

The first active pattern AP1 and the second active pattern AP2 may be arranged on the first insulating layer IL1. In one or more embodiments, the first active pattern AP1 may overlap the first lower conductive layer BML1 in a plan view, and the second active pattern AP2 may overlap the second lower conductive layer BML2 in a plan view. The first and second active patterns AP1 and AP2 may include an oxide semiconductor material, a silicon semiconductor material, or an organic semiconductor material. The first active pattern AP1 may include a first contact area S1, a second contact area D1, and a first channel area CH1 between the first contact area S1 and the second contact area D1, and the second active pattern AP2 may include a third contact area S2, a fourth contact area D2, and a second channel area CH2 between the third contact area S2 and the fourth contact area D2. The first contact area S1 and the second contact area D1 may have higher conductivity than the first channel area CH1, and the third contact area S2 and the fourth contact area D2 may have higher conductivity than the second channel area CH2.

In one or more embodiments, the first and second active patterns AP1 and AP2 may include an oxide semiconductor material. Examples of the oxide semiconductor material may include indium gallium zinc oxide, zinc tin oxide, indium tin zinc oxide, or the like. These may be used alone or in combination with each other. However, the present disclosure is not limited thereto, and in one or more embodiments, the first and second active patterns AP1 and AP2 may include different materials. For example, any one of the first or second active patterns AP1 or AP2 may include an oxide semiconductor material, and the other may include a silicon semiconductor material.

Although FIG. 5 illustrates that the first active pattern AP1 and the second active pattern AP2 are arranged in the same layer, the present disclosure is not limited thereto, and the first active pattern AP1 and the second active pattern AP2 may be arranged in different layers.

The second insulating layer IL2 may be arranged on the first insulating layer IL1, and may cover at least a portion of the first active pattern AP1 and the second active pattern AP2. The second insulating layer ILD2 may include an insulating material. Examples of the insulating material may include silicon oxide, silicon nitride, silicon oxynitride, or the like. These may be used alone or in combination with each other.

The first gate electrode GE1, the second gate electrode GE2, and the first capacitor electrode CPE1 may be arranged on the second insulating layer IL2. The first gate electrode GE1 may overlap the first channel area CH1 of the first active pattern AP1 in a plan view, and the second gate electrode GE2 may overlap the second channel area CH2 of the second active pattern AP2 in a plan view. The first capacitor electrode CPE1 may overlap the third capacitor electrode CPE3 in a plan view, and the first capacitor electrode CPE1 and the third capacitor electrode CPE3 may define the second capacitor CAP2. The first gate electrode GE1, the second gate electrode GE2, and the first capacitor electrode CPE1 may include a conductive material, such as a metal, an alloy, a conductive metal oxide, a conductive metal nitride, a transparent conductive oxide, or the like. In one or more embodiments, the first gate electrode GE1 may contact the first lower conductive layer BML1. In addition, in one or more embodiments, the second gate electrode GE2 may contact the second lower conductive layer BML2.

Although FIG. 5 illustrates that the first gate electrode GE1, the second gate electrode GE2, and the first capacitor electrode CPE1 are arranged in the same layer, the present disclosure is not limited thereto, and the first gate electrode GE1, the second gate electrode GE2, and the first capacitor electrode CPE1 may be arranged in different layers.

The third insulating layer IL3 may be arranged on the second insulating layer IL2, and may cover the first gate electrode GE1, the second gate electrode GE2, and the first capacitor electrode CPE1. The third insulating layer IL3 may include an insulating material. Examples of the insulating material may include silicon oxide, silicon nitride, silicon oxynitride, or the like. These may be used alone or in combination with each other.

The second capacitor electrode CPE2 may be arranged on the third insulating layer IL3. The second capacitor electrode CPE2 may overlap the first capacitor electrode CPE1 in a plan view, and the first capacitor electrode CPE1 and the second capacitor electrode CPE2 may define the first capacitor CAP1. The second capacitor electrode CPE2 may include a conductive material, such as a metal, an alloy, a conductive metal oxide, a conductive metal nitride, a transparent conductive oxide, or the like.

The fourth insulating layer IL4 may be arranged on the third insulating layer IL3, and may cover the second capacitor electrode CPE2. The fourth insulating layer IL4 may include an insulating material. Examples of the insulating material may include silicon oxide, silicon nitride, silicon oxynitride, or the like. These may be used alone or in combination with each other.

The first, second, third, and fourth contact electrodes SE1, DE1, SE2, and DE2 may be arranged on the fourth insulating layer IL4. The first contact electrode SE1 may contact the first contact area S1 of the first active pattern AP1, and the second contact electrode DE1 may contact the second contact area D1 of the first active pattern AP1. The third contact electrode SE2 may contact the third contact area S2 of the second active pattern AP2, and the fourth contact electrode DE2 may contact the fourth contact area D2 of the second active pattern AP2. The first, second, third, and fourth contact electrodes SE1, DE1, SE2, and DE2 may include a conductive material, such as a metal, an alloy, a conductive metal oxide, a conductive metal nitride, a transparent conductive oxide, or the like.

In one or more embodiments, the first contact electrode SE1 may contact the first lower conductive layer BML1, and the third contact electrode SE2 may contact the second lower conductive layer BML2. However, the present disclosure is not limited thereto, when the first gate electrode GE1 contacts the first lower conductive layer BML1, the first contact electrode SE1 may not contact the first lower conductive layer BML1, and when the second gate electrode GE2 contacts the second lower conductive layer BML2, the third contact electrode SE2 may not contact the second lower conductive layer BML2.

The fifth insulating layer IL5, which may be referred to as a first insulating layer in the claims, may be arranged on the fourth insulating layer IL4, and may cover the first, second, third, and fourth contact electrodes SE1, DE1, SE2, and DE2. The fifth insulating layer IL5 may include an insulating material. In one or more embodiments, the fifth insulating layer IL5 may include an organic insulating material. Examples of the organic insulating material may include a photoresist, a polyacrylic resin, a polyimide resin, a polyamide resin, a siloxane resin, an acrylic resin, an epoxy resin, or the like. These may be used alone or in combination with each other.

In one or more embodiments, an upper surface (e.g., a surface spaced apart from the substrate SUB) of the fifth insulating layer IL5 may have a step. The fifth insulating layer IL5 may define a groove H in which at least a portion of the upper surface thereof is recessed in a thickness direction (e.g., toward a lower surface thereof), and a thickness (e.g., a length in the third direction DR3) of the fifth insulating layer IL5 may not be constant. The fifth insulating layer IL5 may generally have a first thickness TH1, and may have a second thickness TH2 that is less than the first thickness TH1 in an area in which the upper surface of the fifth insulating layer IL5 is recessed (e.g., an area in which the groove H is defined).

The first connection electrode CE1 may be arranged on the fifth insulating layer IL5. As described above, the first connection electrode CE1 may be connected to the first transistor TR1. For example, the first connection electrode CE1 may contact the first transistor TR1 through a contact hole CNT penetrating the fifth insulating layer IL5. The position of the first circuit connection portion CP1 may correspond to a position of the contact hole CNT.

The sixth insulating layer IL6, which may be referred to as a second insulating layer in the claims, may be arranged on the fifth insulating layer IL5 (e.g., the first insulating layer in the claims), and may cover at least a portion of the first connection electrode CE1. The sixth insulating layer IL6 may define a first sub-opening SO1 exposing at least a portion of the first connection electrode CE1. In addition, the sixth insulating layer IL6 may define a second sub-opening SO2 corresponding to the groove H. The second sub-opening SO2 may overlap the groove H in a plan view, and the second sub-opening SO2 and the groove H may be spatially connected to each other. The sixth insulating layer IL6 may include an insulating material. In one or more embodiments, the sixth insulating layer IL6 may include an organic insulating material. Examples of the organic insulating material may include a photoresist, a polyacrylic resin, a polyimide resin, a polyamide resin, a siloxane resin, an acrylic resin, an epoxy resin, or the like. These may be used alone or in combination with each other.

The first electrode E1 and the separator SPR may be arranged on the sixth insulating layer IL6. For example, the first electrode E1 and the separator SPR may be spaced apart from each other. The first electrode E1 and the separator SPR may include a conductive material, such as a metal, an alloy, a conductive metal oxide, a conductive metal nitride, a transparent conductive oxide, or the like. In one or more embodiments, the first electrode E1 and the separator SPR may be arranged in the same layer. The first electrode E1 and the separator SPR may include the same material, and may be formed through the same process.

The sixth insulating layer IL6 overlapping the separator SPR in a plan view may define the first sub-opening SO1 or the second sub-opening SO2. A side surface of the separator SPR may protrude outwardly from a side surface of the sixth insulating layer IL6 overlapping the separator SPR in a plan view. The side surface of the separator SPR may protrude further toward an inside of the first sub-opening SO1 and/or an inside of the second sub-opening SO2 than the side surface of the sixth insulating layer IL6 overlapping the separator SPR in a plan view. The separator SPR may have a tip shape that protrudes further outwardly than the sixth insulating layer IL6 arranged below the separator SPR. The sixth insulating layer IL6 and the separator SPR may define an undercut (or eave) structure in which the separator SPR further protrudes toward the first sub-opening SO1 and/or the second sub-opening SO2.

The pixel-defining layer PDL may be arranged on the sixth insulating layer IL6, the first electrode E1, and the separator SPR. The pixel-defining layer PDL may include an insulating material. In one or more embodiments, the pixel-defining layer PDL may include an organic insulating material. Examples of the organic insulating material may include a photoresist, a polyacrylic resin, a polyimide resin, a polyamide resin, a siloxane resin, an acrylic resin, an epoxy resin, or the like. These may be used alone or in combination with each other. In one or more embodiments, the pixel-defining layer PDL may have a selected color.

The pixel-defining layer PDL may define a third sub-opening SO3 corresponding to the first sub-opening SO1. The third sub-opening SO3 may overlap the first sub-opening SO1 in a plan view, and the third sub-opening SO3 and the first sub-opening SO1 may be spatially connected to each other. Accordingly, a first opening OP1 in which the first sub-opening SO1 and the third sub-opening SO3 are connected may be defined, and the first opening OP1 may expose at least a portion of the first connection electrode CE1.

In addition, the pixel-defining layer PDL may define a fourth sub-opening SO4 corresponding to the groove H and the second sub-opening SO2. The fourth sub-opening SO4 may overlap the groove H and the second sub-opening SO2 in a plan view, and the fourth sub-opening SO4, the groove H, and the second sub-opening SO2 may be spatially connected to each other. Accordingly, a second opening OP2 in which the groove H, the second sub-opening SO2, and the fourth sub-opening SO4 are connected may be defined, and the second opening OP2 may expose at least a portion of the fifth insulating layer IL5.

In one or more embodiments, the pixel-defining layer PDL may include a first pixel-defining layer PDL1 covering at least a portion of the first electrode E1, and a second pixel-defining layer PDL2 covering at least a portion of the separator SPR. For example, the first pixel-defining layer PDL1 and the second pixel-defining layer PDL2 may be spaced apart from each other. The first opening OP1 or the second opening OP2 may be defined between the first pixel-defining layer PDL1 and the second pixel-defining layer PDL2.

The first pixel-defining layer PDL1 may cover a peripheral portion (e.g., an edge) of the first electrode E1, and may define a pixel opening exposing at least a portion of the first electrode E1. The first light-emitting area EA1 may be defined by the pixel opening.

The second pixel-defining layer PDL2 overlapping the separator SPR in a plan view may define the third sub-opening SO3 or the fourth sub-opening SO4. The second pixel-defining layer PDL2 may cover at least a portion of a central portion of the separator SPR. A side surface of the second pixel-defining layer PDL2 may be recessed inwardly to a greater degree than the side surface of the separator SPR. That is, the side surface of the separator SPR may protrude outwardly further than the side surface of the second pixel-defining layer PDL2. The side surface of the separator SPR may protrude further into the inside of the first opening OP1 and the inside of the second opening OP2 than the side surface of the second pixel-defining layer PDL2 overlapping the separator SPR in a plan view. That is, at least a portion of the separator SPR may protrude toward the first opening OP1 and/or the second opening OP2, and may be arranged in the first opening OP1 and/or the second opening OP2. The separator SPR may be arranged between the sixth insulating layer IL6 and the second pixel-defining layer PDL2. The separator SPR may have a tip shape that protrudes further outwardly than both the sixth insulating layer IL6 arranged below the separator SPR and the second pixel-defining layer PDL2 arranged above the separator SPR. Because the second pixel-defining layer PDL2 is arranged on the separator SPR, reflectance of the separator SPR may be reduced.

The intermediate layer ML may be arranged on the first electrode E1 and the first pixel-defining layer PDL1. A portion of the intermediate layer ML may be arranged in the pixel opening of the first pixel-defining layer PDL1. In addition, a portion of the intermediate layer ML may be arranged in the first opening OP1 to contact at least a portion of the first connection electrode CE1. In addition, a portion of the intermediate layer ML may be arranged in the second opening OP2.

In one or more embodiments, the intermediate layer ML may include a first functional layer including an organic material, a light-emitting layer arranged on the first functional layer and including a light-emitting material, and a second functional layer arranged on the light-emitting layer and including an organic material. For example, the first functional layer may include a hole injection layer, a hole transport layer, or the like, and the second functional layer may include an electron transport layer, an electron injection layer, or the like.

In one or more embodiments, the intermediate layer ML may have a structure that is separated (or disconnected) by the separator SPR. For example, the first and second functional layers included in the intermediate layer ML may have a structure that is separated (or disconnected) by the separator SPR. Because the separator SPR has a shape protruding toward the inside of the first and second openings OP1 and OP2 (e.g., a tip shape), an area in which the intermediate layer ML is difficult to be deposited may exist, and the intermediate layer ML may have a structure that is separated (or disconnected) in the area. That is, the intermediate layer ML may be disconnected by the shape of the separator SPR.

Because the intermediate layer ML has a structure in which the intermediate layer ML is separated (or disconnected) by the separator SPR, a first dummy layer DP1 may be arranged on the separator SPR and the second pixel-defining layer PDL2. The first dummy layer DP1 may be formed in the same process as the intermediate layer ML, and the first dummy layer DP1 and the intermediate layer ML may be spaced apart from each other. That is, in the process of forming the intermediate layer ML, the intermediate layer ML may be disconnected by the shape of the separator SPR, and the first dummy layer DP1 may be formed. In one or more embodiments, the first dummy layer DP1 may be omitted.

The electrode layer E2 (e.g., the second electrodes E21, E22, and E23) may be arranged on the intermediate layer ML. The electrode layer E2 may include a conductive material, such as a metal, an alloy, a conductive metal oxide, a conductive metal nitride, a transparent conductive oxide, or the like. In one or more embodiments, the electrode layer E2 may have a single-layer structure. However, the present disclosure is not limited thereto, and in one or more embodiments, the electrode layer E2 may have a multi-layer structure in which a plurality of conductive layers are stacked. For example, the electrode layer E2 may have a two-layer structure in which a first layer including a metal and a second layer arranged on the first layer and including a transparent conductive oxide are stacked.

In one or more embodiments, the electrode layer E2 may have a structure separated (or disconnected) by the separator SPR. For example, as illustrated in FIG. 4, the electrode layer E2 may be separated (or disconnected) into the second electrode E21 of the first light-emitting element LE1 arranged in the first open area OA1 of the separator SPR, the second electrode E22 of the second light-emitting element LE2 arranged in the second open area OA2 of the separator SPR, and the second electrode E23 of the third light-emitting element LE3 arranged in the third open area OA3 of the separator SPR. That is, the second electrodes E21, E22, and E23 may be electrically independent of each other.

Because the separator SPR has a shape protruding toward the inside of the first and second openings OP1 and OP2 (e.g., a tip shape), an area in which it is difficult to deposit the electrode layer E2 may exist, and the electrode layer E2 may have a structure separated (or disconnected) in the area. That is, the electrode layer E2 may be disconnected by the shape of the separator SPR.

Because the electrode layer E2 has a structure in which the electrode layer E2 is separated (or disconnected) by the separator SPR, the second dummy layer DP2 may be arranged on the separator SPR and the second pixel-defining layer PDL2. The second dummy layer DP2 may be arranged on the first dummy layer DP1. The second dummy layer DP2 may be formed in the same process as the electrode layer E2, and the second dummy layer DP2 and the electrode layer E2 may be spaced apart from each other. That is, in a process of forming the electrode layer E2, the electrode layer E2 may be disconnected by the shape of the separator SPR, and the second dummy layer DP2 may be formed. In one or more embodiments, the second dummy layer DP2 may be omitted.

As illustrated in FIG. 5, the second electrode E21 of the first light-emitting element LE1 may be connected to the first connection electrode CE1. For example, the second electrode E21 may contact the first light-emitting connection portion CN1 of the first connection electrode CE1. In this case, a deposition angle of a deposition process forming the electrode layer E2 may be greater than a deposition angle of a deposition process forming the intermediate layer ML. Accordingly, the second electrode E21 may be formed to contact the first connection electrode CE1 while covering the intermediate layer ML disconnected by the separator SPR, and may be connected to the first transistor TR1 through the first connection electrode CE1.

The encapsulation layer ENC may be arranged on the electrode layer E2. The encapsulation layer ENC may reduce or prevent impurities, moisture, outside air, or the like penetrating into the first light-emitting element LE1 from outside. The encapsulation layer ENC may include at least one inorganic encapsulation layer and at least one organic encapsulation layer.

The display device DD according to one or more embodiments of the present disclosure may include the connection electrodes CE1, CE2, and CE3 and the separator SPR. The electrode layer E2 arranged above the first electrode E1 may be easily connected to the pixel-driving circuits PC1, PC2, and PC3 through the connection electrodes CE1, CE2, and CE3, and may be easily separated from each other through the separator SPR. Accordingly, even when a light-emitting element is deteriorated, a gate-source voltage (Vgs) of a driving transistor of each of the pixel-driving circuits PC1, PC2, and PC3 may not change (e.g., may not significantly change). Accordingly, a range of change in driving current due to deterioration of the light-emitting element may be reduced. Accordingly, an afterimage defect of the display device DD due to an increase in usage time may be reduced, and a lifespan of the display device DD may be improved.

In addition, because the separator SPR may be formed through the same process as the first electrode E1, a separate additional process for manufacturing a component that disconnects the intermediate layer ML and the electrode layer E2 may not be required. Accordingly, a manufacturing process of the display device DD may be simplified, and efficiency of the manufacturing process may be improved.

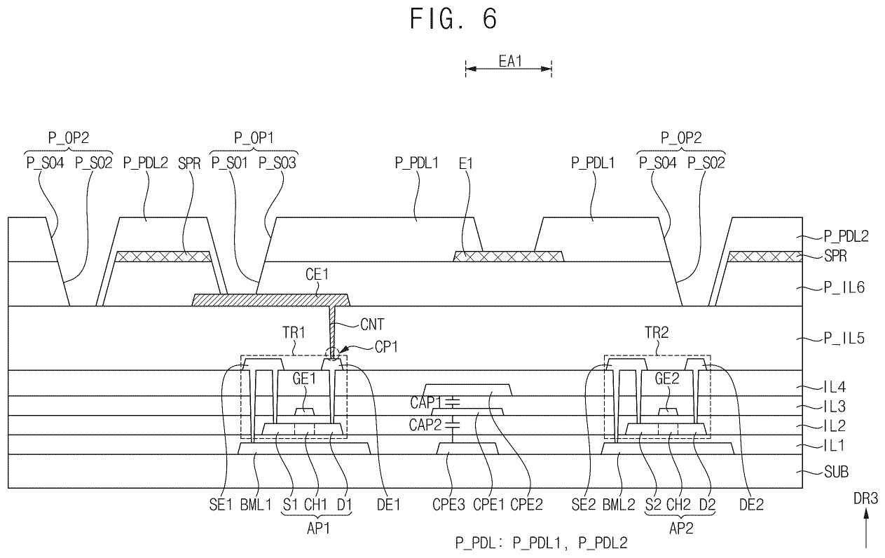

FIGS. 6, 7, and 8 are cross-sectional views illustrating a method of manufacturing a display device according to one or more embodiments of the present disclosure.

A method of manufacturing a display device described with reference to FIGS. 6, 7, and 8 may be a method of manufacturing the display device DD described with reference to FIGS. 1A, 1B, 2A, 2B, 3, 4, and 5. Hereinafter, redundant descriptions will be omitted or simplified.

Referring to FIG. 6, a first lower conductive layer BML1, a second lower conductive layer BML2, a first transistor TR1, a second transistor TR2, a first capacitor CAP1, a second capacitor CAP2, and first, second, third, and fourth insulating layers IL1, IL2, IL3, and IL4 may be formed on a substrate SUB.

A preliminary fifth insulating layer P_IL5 may be formed on the fourth insulating layer IL4. In one or more embodiments, the preliminary fifth insulating layer P_IL5 may include an organic insulating material. Examples of the organic insulating material may include a photoresist, a polyacrylic resin, a polyimide resin, a polyamide resin, a siloxane resin, an acrylic resin, an epoxy resin, or the like. These may be used alone or in combination with each other.

A first connection electrode CE1 may be formed on the preliminary fifth insulating layer P_IL5. The first connection electrode CE1 may be connected to the first transistor TR1. For example, the first connection electrode CE1 may contact the first transistor TR1 through a contact hole CNT penetrating the preliminary fifth insulation layer P_IL5. A position of a first circuit connection portion CP1 in which the first connection electrode CE1 and the first transistor TR1 are connected may correspond to a position of the contact hole CNT.

A preliminary sixth insulating layer P_IL6 may be formed on the preliminary fifth insulating layer P_IL5, and may cover at least a portion of the first connection electrode CE1. The preliminary sixth insulating layer P_IL6 may define a preliminary first sub-opening P_SO1 exposing at least a portion of the first connection electrode CE1. In addition, the preliminary sixth insulating layer P_IL6 may define a preliminary second sub-opening P_SO2 exposing at least a portion of the preliminary fifth insulating layer P_IL5. In one or more embodiments, the preliminary sixth insulating layer P_IL6 may include an organic insulating material. Examples of the organic insulating material may include a photoresist, a polyacrylic resin, a polyimide resin, a polyamide resin, a siloxane resin, an acrylic resin, an epoxy resin, or the like. These may be used alone or in combination with each other.

A first electrode E1 and a separator SPR may be formed on the preliminary sixth insulating layer P_IL6. The first electrode E1 and the separator SPR may include a conductive material, such as a metal, an alloy, a conductive metal oxide, a conductive metal nitride, a transparent conductive oxide, or the like. In one or more embodiments, the first electrode E1 and the separator SPR may be arranged in the same layer. The first electrode E1 and the separator SPR may include the same material, and may be formed through the same process. The preliminary sixth insulating layer P_IL6 overlapping the separator SPR in a plan view may define the preliminary first sub-opening P_SO1 or the preliminary second sub-opening P_SO2.

A preliminary pixel-defining layer P_PDL may be formed on the preliminary sixth insulating layer P_IL6, the first electrode E1, and the separator SPR. In one or more embodiments, the preliminary pixel-defining layer P_PDL may include an organic insulating material. Examples of the organic insulating material may include a photoresist, a polyacrylic resin, a polyimide resin, a polyamide resin, a siloxane resin, an acrylic resin, an epoxy resin, or the like. These may be used alone or in combination with each other. The preliminary pixel-defining layer P_PDL may have a selected color.

The preliminary pixel-defining layer P_PDL may define a preliminary third sub-opening P_SO3 corresponding to the preliminary first sub-opening P_SO1. The preliminary third sub-opening P_SO3 may overlap the preliminary first sub-opening P_SO1 in a plan view, and the preliminary third sub-opening P_SO3 and the preliminary first sub-opening P_SO1 may be spatially connected to each other. Accordingly, a preliminary first opening P_OP1 in which the preliminary first sub-opening P_SO1 and the preliminary third sub-opening P_SO3 are connected may be defined, and the preliminary first opening P_OP1 may expose at least a portion of the first connection electrode CE1.

In addition, the preliminary pixel-defining layer P_PDL may define a preliminary fourth sub-opening P_SO4 corresponding to the preliminary second sub-opening P_SO2. The preliminary fourth sub-opening P_SO4 may overlap the preliminary second sub-opening P_SO2 in a plan view, and the preliminary fourth sub-opening P_SO4 and the preliminary second sub-opening P_SO2 may be spatially connected to each other. Accordingly, a preliminary second opening P_OP2 in which the preliminary second sub-opening P_SO2 and the preliminary fourth sub-opening P_SO4 are connected may be defined, and the preliminary second opening P_OP2 may expose at least a portion of the preliminary fifth insulating layer P_IL5.

In one or more embodiments, the preliminary pixel-defining layer P_PDL may include a preliminary first pixel-defining layer P_PDL1 covering at least a portion of the first electrode E1 and a preliminary second pixel-defining layer P_PDL2 covering at least a portion of the separator SPR. For example, the preliminary first pixel-defining layer P_PDL1 and the preliminary second pixel-defining layer P_PDL2 may be spaced apart from each other. The preliminary first opening P_OP1 or the preliminary second opening P_OP2 may be defined between the preliminary first pixel-defining layer P_PDL1 and the preliminary second pixel-defining layer P_PDL2.

The preliminary first pixel-defining layer P_PDL1 may cover a peripheral portion (e.g., an edge) of the first electrode E1, and may define a preliminary pixel opening exposing at least a portion of the first electrode E1. The preliminary second pixel-defining layer P_PDL2 may cover an upper surface (e.g., a surface spaced apart from the substrate SUB) of the separator SPR. In one or more embodiments, the preliminary second pixel-defining layer P_PDL2 may cover the upper surface and a side surface of the separator SPR and a side surface of the preliminary sixth insulating layer P_IL6 overlapping the separator SPR in a plan view. The preliminary second pixel-defining layer P_PDL2 overlapping the separator SPR in a plan view may define the preliminary third sub-opening P_SO3 or the preliminary fourth sub-opening P_SO4.

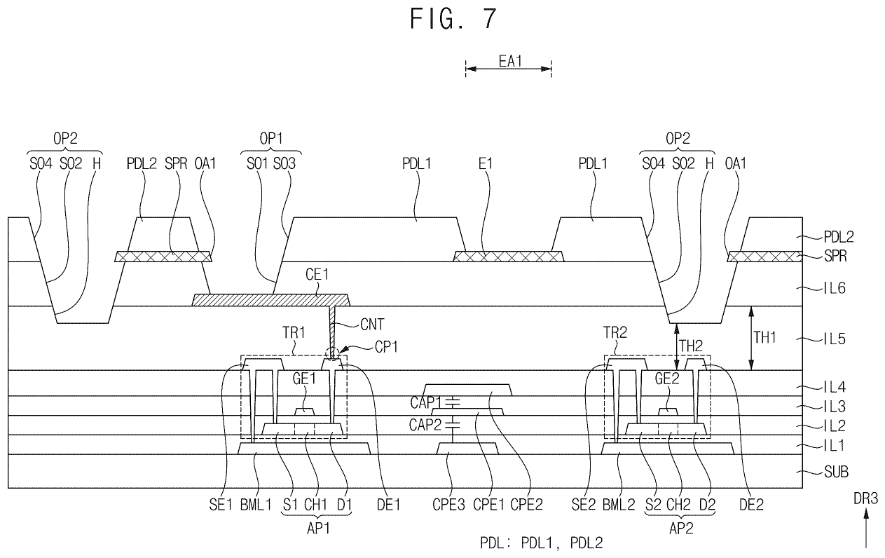

Referring to FIGS. 6 and 7, a portion of the preliminary fifth insulating layer P_IL5 may be removed to form a fifth insulating layer IL5, a portion of the preliminary sixth insulating layer P_IL6 may be removed to form a sixth insulating layer IL6, and a portion of the preliminary pixel-defining layer P_PDL may be removed to form a pixel-defining layer PDL.

In one or more embodiments, an ashing process may be performed to remove a portion(s) of the preliminary fifth insulating layer P_IL5, a portion(s) of the preliminary sixth insulating layer P_IL6, and a portion(s) of the preliminary pixel-defining layer P_PDL, so that the fifth insulating layer IL5, the sixth insulating layer IL6, and the pixel-defining layer PDL may be formed, respectively. Because each of the preliminary fifth insulating layer P_IL5, the preliminary sixth insulating layer P_IL6, and the preliminary pixel-defining layer P_PDL may include an organic insulating material, the portions of each may be removed through the ashing process. For example, in the ashing process, the preliminary fifth insulating layer P_IL5, the preliminary sixth insulating layer P_IL6, and the preliminary pixel-defining layer P_PDL may be ashed through oxygen (O₂) plasma treatment.

The portion of the preliminary fifth insulating layer P_IL5 overlapping the preliminary second opening P_OP2 in a plan view may be removed to form the fifth insulating layer IL5 defining a groove H in which at least a portion of an upper surface is recessed in a thickness direction (e.g., toward a lower surface). The upper surface of the fifth insulating layer IL5 may have a step, and a thickness of the fifth insulating layer IL5 may not be constant. The fifth insulating layer IL5 may generally have a first thickness TH1, and may have a second thickness TH2 that is less than the first thickness TH1 in an area in which the upper surface is recessed (e.g., an area in which the groove H is defined).

The portion of the preliminary sixth insulating layer P_IL6 in the preliminary first opening P_OP1 and the preliminary second opening P_OP2 may be removed to form the sixth insulating layer IL6 defining a first sub-opening SO1 and a second sub-opening SO2. The first sub-opening SO1 may expose at least a portion of the first connection electrode CE1, and the second sub-opening SO2 may be spatially connected to the groove H.

The portion of the preliminary pixel-defining layer P_PDL in the preliminary first opening P_OP1, the preliminary second opening P_OP2, and the preliminary pixel opening may be removed to form the pixel-defining layer PDL defining a third sub-opening SO3, a fourth sub-opening SO4, and a pixel opening.

The third sub-opening SO3 may be spatially connected to the first sub-opening SO1, and a first opening OP1 in which the first sub-opening SO1 and the third sub-opening SO3 are connected may be defined. The fourth sub-opening SO4 may be spatially connected to the groove H and the second sub-opening SO2, and a second opening OP2 in which the groove H, the second sub-opening SO2, and the fourth sub-opening SO4 are connected may be defined.

A portion of the preliminary first pixel-defining layer P_PDL1 may be removed to form a first pixel-defining layer PDL1 covering at least a portion of the first electrode E1, and a portion of the preliminary second pixel-defining layer P_PDL2 may be removed to form a second pixel-defining layer PDL2 covering at least a portion of the separator SPR. For example, the first opening OP1 or the second opening OP2 may be defined between the first pixel-defining layer PDL1 and the second pixel-defining layer PDL2. The second pixel-defining layer PDL2 arranged on the separator SPR may serve to reduce reflectance of the separator SPR.

As the preliminary sixth insulating layer P_IL6 and the preliminary pixel-defining layer P_PDL are removed in the preliminary first opening P_OP1 and the preliminary second opening P_OP2 to form the sixth insulating layer IL6 and the pixel-defining layer PDL defining the first opening OP1 and the second opening OP2, the separator SPR may protrude into an inside the first opening OP1 and an inside of the second opening OP2.

A side surface of the separator SPR may protrude further outwardly than a side surface of each of the sixth insulating layer IL6 and the second pixel-defining layer PDL2 overlapping the separator SPR in a plan view, and the separator SPR may have a tip shape. The sixth insulating layer IL6 overlapping the separator SPR in a plan view and the separator SPR may define an undercut (or eave) structure in which the separator SPR protrudes further toward the first opening OP1 and the second opening OP2. That is, at least a portion of the separator SPR may be arranged in the first opening OP1 and the second opening OP2.

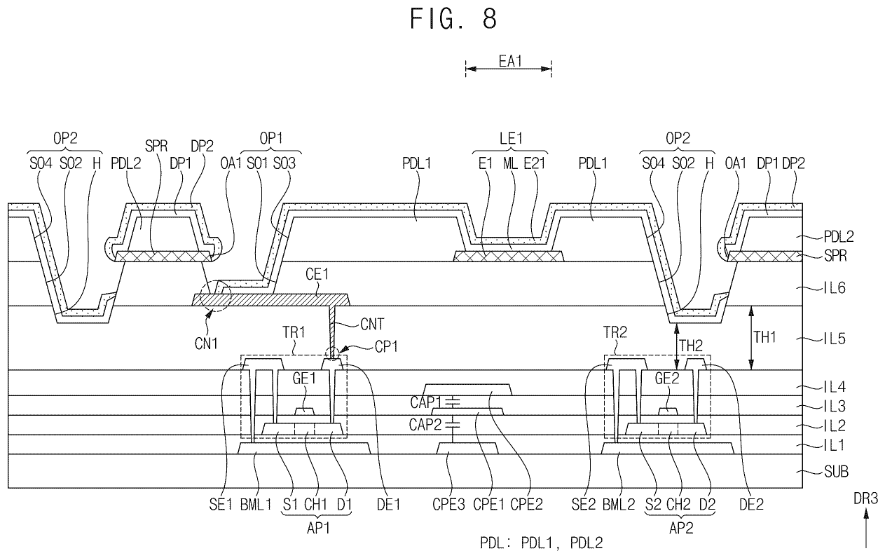

Referring to FIG. 8, an intermediate layer ML and a second electrode E21 may be sequentially formed on the first electrode E1 and the first pixel-defining layer PDL1. A first dummy layer DP1 and a second dummy layer DP2 may be sequentially formed on the separator SPR and the second pixel-defining layer PDL2.

In one or more embodiments, the intermediate layer ML may be formed in a structure separated (or disconnected) by the separator SPR. As the separator SPR has a shape protruding toward the inside of the first and second openings OP1 and OP2 (e.g., a tip shape), an area in which the intermediate layer ML is difficult to be deposited may exist, and the intermediate layer ML may be disconnected in the area.

In a process of forming the intermediate layer ML, the intermediate layer ML may be disconnected due to the shape of the separator SPR, and the first dummy layer DP1 may be formed. That is, the first dummy layer DP1 may be formed in the same process as the intermediate layer ML, and the first dummy layer DP1 and the intermediate layer ML may be spaced apart from each other.

In one or more embodiments, the second electrode E21 may be formed in a structure separated (or disconnected) by the separator SPR. As the separator SPR has a shape protruding toward the inside of the first and second openings OP1 and OP2 (e.g., a tip shape), an area in which the second electrode E21 is difficult to be deposited may exist, and the second electrode E21 may be disconnected in the area.

In a process of forming the second electrode E21, the second electrode E21 may be disconnected due to the shape of the separator SPR, and the second dummy layer DP2 may be formed. That is, the second dummy layer DP2 may be formed in the same process as the second electrode E21, and the second dummy layer DP2 and the second electrode E21 may be spaced apart from each other.

The second electrode E21 of a first light-emitting element LE1 may be connected to the first connection electrode CE1. For example, the second electrode E21 may contact the first light-emitting connection portion CN1 of the first connection electrode CE1. The second electrode E21 may be formed to contact the first connection electrode CE1 while covering the intermediate layer ML disconnected by the separator SPR, and may be connected to the first transistor TR1 through the first connection electrode CE1.

Referring back to FIG. 5, an encapsulation layer ENC may be formed on the second electrode E21, and accordingly, the display device DD illustrated in FIG. 5 may be manufactured.

In the method of manufacturing the display device according to one or more embodiments of the present disclosure, the separator SPR that separates the intermediate layer ML and the electrode layer E2 may be formed through the same process as the first electrode E1. Because a separate additional process (e.g., a photolithography process) of forming a component that separates the intermediate layer ML and the electrode layer E2 is not required, a manufacturing process of the display device may be simplified, and efficiency of the manufacturing process may be improved.

The display device DD according to one or more embodiments of the present disclosure may be applied to various electronic devices. An electronic device according to one or more embodiments of the present disclosure may include the display device DD described above, and may further include a module or device having other additional functions in addition to the display device DD.

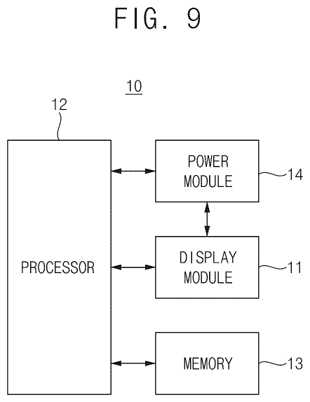

FIG. 9 is a block diagram illustrating an electronic device according to one or more embodiments of the present disclosure. Referring to FIG. 9, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), or an image signal processor (ISP).

The memory 13 may store data information necessary for operation of the processor 12 or the display module 11. When the processor 12 executes an application stored in the memory 13, an input image data signal and/or a control signal may be transmitted to the display module 11, and the display module 11 may process the received signal and output image information through a display screen.

The power module 14 may include a power supply module, such as a power adapter or a battery device, and a power conversion module that converts power supplied by the power supply module to generate power required for operation of the electronic device 10.

At least one of components of the electronic device 10 may be included in the display device according to embodiments of the present disclosure described above. In addition, some of individual modules functionally included in one module may be included in the display device, and other portions may be provided separately from the display device. For example, the display device may include the display module 11, and the processor 12, the memory 13, and the power module 14 may be provided in form of other devices within the electronic device 10 other than the display device.

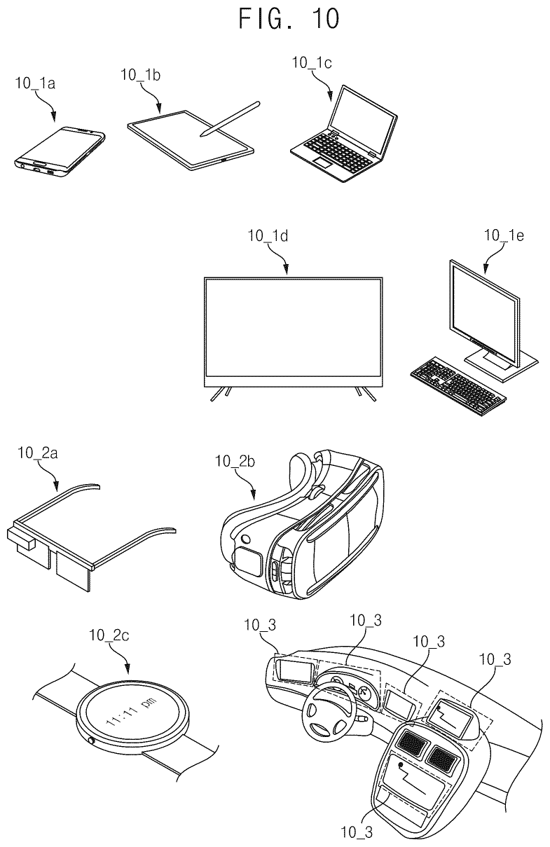

FIG. 10 is a schematic diagram of electronic devices according to various embodiments of the present disclosure. FIG. 10 is a schematic diagram illustrating an electronic device according to various embodiments.

Referring to FIG. 10, various electronic devices to which the display device according to one or more embodiments of the present disclosure is applied may include not only image display electronic devices, such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a Center Information Display (CID) arranged on a cluster, a center fascia, and dashboard of a car, and a room mirror display, or the like.

The present disclosure can be applied to various display devices and electronic devices. For example, the present disclosure is applicable to various display devices, such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the aspects of the present disclosure. Accordingly, all such modifications are intended to be included within the scope of the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, with functional equivalents thereof to be included therein.

What is claimed is:

1. A display device comprising:
a transistor above a substrate;
a first insulating layer above the transistor;
a second insulating layer above the first insulating layer and defining a first sub-opening;
a light-emitting element above the second insulating layer, electrically connected to the transistor, and comprising a first electrode, an intermediate layer above the first electrode, and a second electrode above the intermediate layer;
a pixel-defining layer above the second insulating layer, covering at least a portion of the first electrode, and defining a third sub-opening, wherein the third sub-opening overlaps the first sub-opening in a plan view and is connected to the first sub-opening to define a first opening; and
a separator between the second insulating layer and the pixel-defining layer, and protruding into the first opening.

2. The display device of claim 1, wherein the separator and the first electrode are at a same layer.

3. The display device of claim 1, wherein the separator and the first electrode comprise a same material.

4. The display device of claim 1, wherein the first insulating layer defines a groove in a recessed portion of an upper surface of the first insulating layer,
wherein the second insulating layer further defines a second sub-opening overlapping the groove in the plan view,
wherein the pixel-defining layer further defines a fourth sub-opening overlapping the groove and the second sub-opening in the plan view, and
wherein the groove, the second sub-opening, and the fourth sub-opening are connected to define a second opening.

5. The display device of claim 4, wherein at least a portion of the separator protrudes into the second opening.

6. The display device of claim 1, wherein the pixel-defining layer comprises:
a first pixel-defining layer covering at least a portion of the first electrode; and
a second pixel-defining layer covering at least a portion of the separator.

7. The display device of claim 1, wherein the second electrode is separated by the separator.

8. The display device of claim 1, wherein the first insulating layer, the second insulating layer, and the pixel-defining layer comprise an organic insulating material.

9. The display device of claim 1, further comprising a connection electrode above the first insulating layer, electrically connected to the transistor, and having a portion exposed by the first opening.

10. The display device of claim 9, wherein the second electrode contacts the connection electrode in the first opening.

11. A method of manufacturing a display device, the method comprising:
forming a transistor above a substrate;
forming a first insulating layer above the transistor;
forming a second insulating layer defining a first sub-opening above the first insulating layer;
forming a pixel-defining layer defining a third sub-opening above the second insulating layer, wherein the third sub-opening is connected to the first sub-opening to define a first opening; and
forming a first electrode of a light-emitting element and a separator above the second insulating layer, a portion of the separator protruding into the first opening.

12. The method of claim 11, wherein the first electrode and the separator are formed through a same process.

13. The method of claim 11, wherein the first electrode and the separator are at a same layer.

14. The method of claim 11, wherein the first insulating layer defines a groove at a recessed portion of an upper surface of the first insulating layer,
wherein the second insulating layer further defines a second sub-opening overlapping the groove in a plan view,
wherein the pixel-defining layer further defines a fourth sub-opening overlapping the groove and the second sub-opening in the plan view, and
wherein the groove, the second sub-opening, and the fourth sub-opening are connected to define a second opening.

15. The method of claim 14, wherein at least a portion of the separator protrudes into the second opening.

16. The method of claim 14, wherein the forming of the first insulating layer comprises:
forming a preliminary first insulating layer above the transistor; and
removing a portion of the preliminary first insulating layer to form the first insulating layer defining the groove,
wherein the forming of the second insulating layer comprises:
forming a preliminary second insulating layer defining a preliminary first sub-opening and a preliminary second sub-opening above the preliminary first insulating layer; and
removing a portion of the preliminary second insulating layer in the preliminary first sub-opening and the preliminary second sub-opening to form the second insulating layer defining the first sub-opening and the second sub-opening,
wherein the forming of the pixel-defining layer comprises:
forming a preliminary pixel-defining layer covering the separator and defining a preliminary third sub-opening connected to the preliminary first sub-opening, and a preliminary fourth sub-opening connected to the preliminary second sub-opening, above the preliminary second insulating layer; and
removing a portion of the preliminary pixel-defining layer in the preliminary third sub-opening and the preliminary fourth sub-opening to form the pixel-defining layer defining the third sub-opening and the fourth sub-opening, and
wherein the portion of the preliminary first insulating layer, the portion of the preliminary second insulating layer, and the portion of the preliminary pixel-defining layer are removed through an ashing process.

17. The method of claim 11, further comprising:
forming an intermediate layer of the light-emitting element above the pixel-defining layer; and
forming a second electrode of the light-emitting element above the intermediate layer,
wherein the intermediate layer and the second electrode are separated by the separator.

18. The method of claim 17, further comprising forming a connection electrode above the first insulating layer, having a portion exposed by the first opening, and electrically connected to the transistor and the second electrode.

19. The method of claim 11, wherein the first insulating layer, the second insulating layer, and the pixel-defining layer comprise an organic insulating material.

20. An electronic device comprising:
a display device; and
a power module configured to supply power to the display device,
wherein the display device comprises:
a transistor above a substrate;
a first insulating layer above the transistor;
a second insulating layer above the first insulating layer and defining a first sub-opening;
a light-emitting element above the second insulating layer, electrically connected to the transistor, and comprising a first electrode, an intermediate layer above the first electrode, and a second electrode above the intermediate layer;
a pixel-defining layer above the second insulating layer, covering at least a portion of the first electrode, and defining a third sub-opening overlapping the first sub-opening in a plan view and connected to the first sub-opening to define a first opening; and
a separator between the second insulating layer and the pixel-defining layer, and having a portion protruding into the first opening.
